(19) United States
(12) Patent Application Publication
(10) Pub. No.: US 2025/0321620 A1
(43) Pub. Date: Oct. 16, 2025

(54) ELECTRONIC DEVICE

(71) Applicant: Samsung Display Co., LTD., Yongin-si (KR)

(72) Inventors: SANGHUN PARK, Yongin-si (KR); YOUNGMIN PARK, Yongin-si (KR); YONGSUB SO, Yongin-si (KR); BO-HWAN LEE, Yongin-si (KR)

(21) Appl. No.: 19/057,383

(22) Filed: Feb. 19, 2025

(30) Foreign Application Priority Data
Apr. 11, 2024 (KR) 10-2024-0048600

(51) Int. Cl. G06F 1/16; G06F 3/044; H10H 29/32; H10H 29/37; H10H 29/854

(52) U.S. Cl. CPC G06F 1/1643; G06F 1/1618; G06F 1/1656; G06F 3/0446; H10H 29/32; H10H 29/37; H10H 29/854

(57) ABSTRACT

An electronic device includes a display panel including a folding area folded about a folding axis extending in a first direction and non-folding areas spaced apart from each other in a second direction crossing the first direction with the folding area therebetween, an input sensing layer disposed on the display panel, and a window disposed on the input sensing layer. The input sensing layer includes normal patterns that overlap the non-folding areas and include normal openings defined therein, respectively, folding patterns that overlap the folding area and include folding openings defined therein, respectively, normal dummy patterns disposed in the normal openings, and folding dummy patterns that are disposed in the folding openings and that have a smaller area than an area of the normal dummy patterns.

This application claims priority to Korean Patent Application No. 10-2024-0048600, filed on Apr. 11, 2024, and all the benefits accruing therefrom under 35 U.S.C. § 119, the content of which in its entirety is herein incorporated by reference.

### BACKGROUND

### 1. Field

Embodiments of the disclosure described herein relate to a foldable electronic device.

### 2. Description of the Related Art

Various electronic devices, such as a television, a mobile phone, a tablet computer, a game machine, and the like, are being developed. In addition, flexible electronic devices including a flexible display panel that is slidable or foldable are being developed. Unlike a rigid electronic device, a flexible electronic device is foldable, rollable, or bendable. The flexible electronic device whose shape is able to be changed in various ways may be carried regardless of the size of the existing screen, and thus user convenience may be improved. Improved folding characteristics in a folding area is desired for a window included in flexible electronic device.

### SUMMARY

Embodiments of the disclosure provide an electronic device including an input sensing layer having uniform sensing sensitivity in a folding area and non-folding areas.

In an embodiment of the disclosure, an electronic device includes a display panel including a folding area folded about a folding axis extending in a first direction and non-folding areas spaced apart from each other in a second direction crossing the first direction with the folding area therebetween, an input sensing layer disposed on the display panel, and a window disposed on the input sensing layer. The input sensing layer includes normal patterns that overlap the non-folding areas and include normal openings defined therein, respectively, folding patterns that overlap the folding area and include folding openings defined therein, respectively, normal dummy patterns disposed in the normal openings, and folding dummy patterns that are disposed in the folding openings and that have a smaller area than the normal dummy patterns.

In an embodiment, the window may include a base substrate including a pattern area that overlaps the folding area and that is recessed in a direction toward the display panel and flat areas that overlap the non-folding areas, a resin layer disposed on the pattern area, a protective layer disposed over the base substrate, and a window adhesive layer disposed between the base substrate and the protective layer.

In an embodiment, the pattern area may have a decreasing thickness toward the center of the folding area from boundaries between the folding area and the non-folding areas.

In an embodiment, the resin layer may have a shape corresponding to a recessed area of the pattern area.

In an embodiment, areas of the folding dummy patterns may be decreased toward the center of the folding area from the boundaries between the folding area and the non-folding areas.

In an embodiment, the folding dummy patterns may have the same area as each other, and the normal dummy patterns may have the same area as each other.

In an embodiment, each of the normal openings, the folding openings, the normal dummy patterns, and the folding dummy patterns may have a rhombic shape.

In an embodiment, the number of folding openings defined in one folding pattern and the number of folding dummy patterns disposed in the one folding pattern may be n times n (n being a natural number greater than 0).

In an embodiment, the number of normal openings defined in one normal pattern may be the same as the number of folding openings defined in one folding pattern, and the number of normal dummy patterns disposed in the one normal pattern may be the same as the number of folding dummy patterns disposed in the one folding pattern.

In an embodiment, the input sensing layer may include a first sensing insulation layer disposed on the display panel, a first conductive pattern layer that is disposed on the first sensing insulation layer and that includes some of the normal patterns and some of the folding patterns, a second sensing insulation layer that is disposed on the first sensing insulation layer and that covers the first conductive pattern layer, a second conductive pattern layer that is disposed on the second sensing insulation layer and that includes remaining (the other) normal patterns, remaining (the other) folding patterns, the normal dummy patterns, and the folding dummy patterns, and a third sensing insulation layer that is disposed on the second sensing insulation layer and that covers the second conductive pattern layer.

In an embodiment, the normal patterns, the folding patterns, the normal dummy patterns, and the folding dummy patterns included in the second conductive layer may be implemented with mesh lines that extend in inclined directions crossing the first direction and the second direction, and the mesh lines may define mesh openings.

In an embodiment, the display panel may include a base layer, a circuit element layer including transistors and insulating layers disposed on the base layer, a display element layer including light emitting elements, each of which includes a first electrode, a second electrode, and an emissive layer connected with the transistors, and a pixel defining layer having light emitting openings defined therein to expose the first electrodes, and an encapsulation layer that is disposed on the display element layer and that includes inorganic layers and an organic layer disposed between the inorganic layers.

In an embodiment, the mesh lines may be disposed on the pixel defining layer, and the mesh openings may overlap the light emitting openings.

In an embodiment, the first sensing insulation layer may be directly disposed on the encapsulation layer.

In an embodiment, each of the normal openings, the folding openings, the normal dummy patterns, and the folding dummy patterns may have a circular shape or a quadrangular shape.

In an embodiment, outer peripheries of the normal patterns may have the same shape as outer peripheries of the folding patterns.

In an embodiment, the folding axis may be defined above an upper surface of the window. In a first mode, the electronic device may be folded in an in-folding manner such that portions of the upper surface of the window that overlap the non-folding areas face each other, and in a second mode, the electronic device may be unfolded.

In an embodiment, the folding axis may be defined below a rear surface of the display panel. In a first mode, the electronic device may be folded in an out-folding manner such that portions of the rear surface of the display panel that overlap the non-folding areas face each other, and in a second mode, the electronic device may be unfolded.

In an embodiment, the electronic device may further include a support plate that is disposed under the display panel and that has holes defined therein to overlap the folding area.

In an embodiment, the display panel may include a first area that overlaps the non-folding areas and the folding area, a second area spaced apart from the first area in the second direction, and a bending area disposed between the first area and the second area, and the bending area may be bent about a bending axis extending in the first direction.

### BRIEF DESCRIPTION OF THE DRAWINGS

The above and other embodiments, advantages and features of the disclosure will become apparent by describing in detail embodiments thereof with reference to the accompanying drawings.

FIG. 1A is a perspective view illustrating an embodiment of an electronic device.

FIG. 1B is a perspective view illustrating an embodiment of the electronic device.

FIG. 1C is a perspective view illustrating an embodiment of the electronic device.

FIG. 1D is a perspective view illustrating an embodiment of the electronic device.

FIG. 2A is a perspective view illustrating an embodiment of an electronic device.

FIG. 2B is a perspective view illustrating an embodiment of the electronic device.

FIG. 2C is a perspective view illustrating an embodiment of the electronic device.

FIG. 3 is an exploded perspective view illustrating an embodiment of an electronic device.

FIG. 4 is a cross-sectional view illustrating a portion corresponding to line I-I′ of FIG. 3.

FIG. 5A is a plan view of an embodiment of a display panel.

FIG. 5B is a cross-sectional view of an embodiment of the electronic device.

FIG. 6 is a cross-sectional view of an embodiment of the electronic device.

FIG. 7 is a plan view of an embodiment of an input sensing layer according to the disclosure.

FIG. 8 is an enlarged plan view illustrating area TT′ of FIG. 7.

FIG. 9 is a plan view of an embodiment of sensing patterns according to the disclosure.

FIG. 10 is a plan view of an embodiment of sensing patterns according to the disclosure.

FIG. 11 is a plan view of an embodiment of sensing patterns according to the disclosure.

FIG. 12 is a plan view of an embodiment of sensing patterns according to the disclosure.

FIG. 13 is a plan view of an embodiment of sensing patterns according to the disclosure.

FIG. 14 is a plan view of an embodiment of an input sensing layer according to the disclosure.

FIG. 15 is a block diagram illustrating an electronic device according to an embodiment.

### DETAILED DESCRIPTION

In this specification, when it is mentioned that a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the application.

Hereinafter, embodiments of the disclosure will be described with reference to the accompanying drawings.

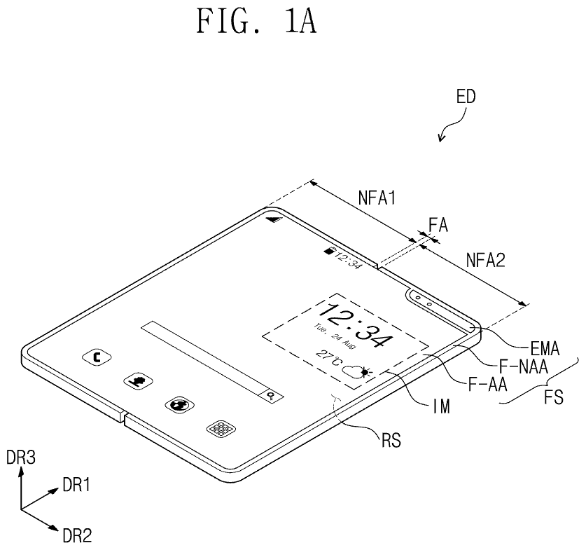

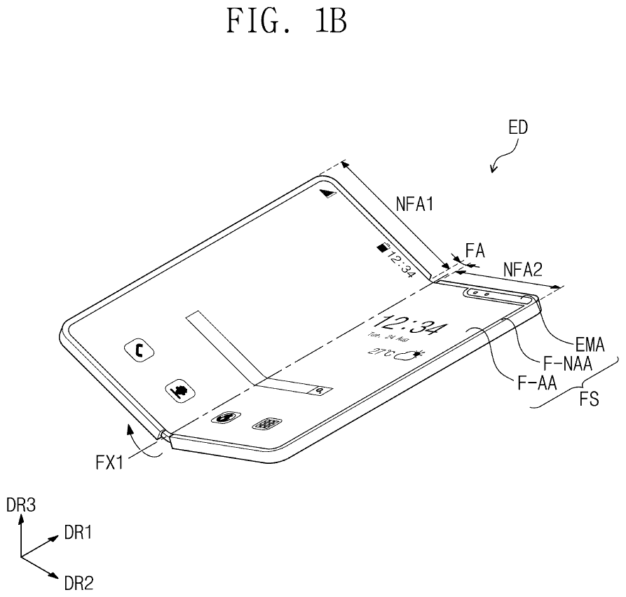

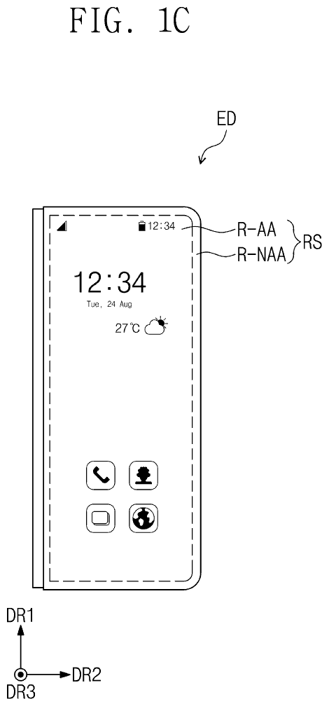

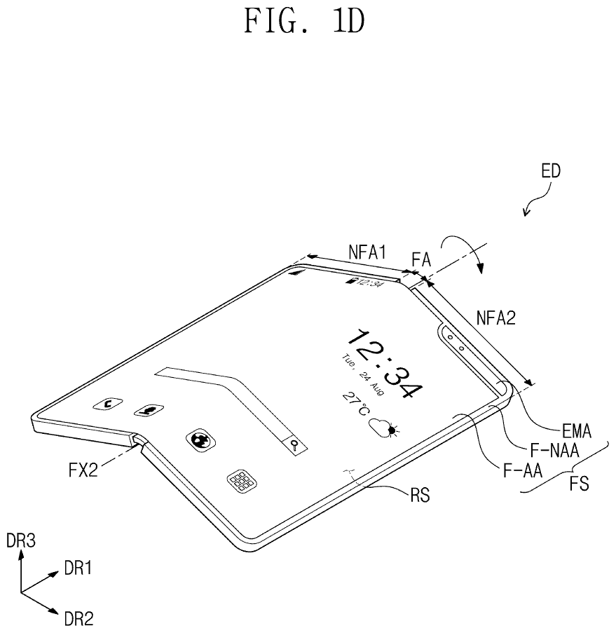

FIG. 1A is a perspective view illustrating an embodiment of an electronic device. FIG. 1B is a perspective view illustrating an embodiment of the electronic device. FIG. 1C is a perspective view illustrating an embodiment of the electronic device. FIG. 1D is a perspective view illustrating an embodiment of the electronic device.

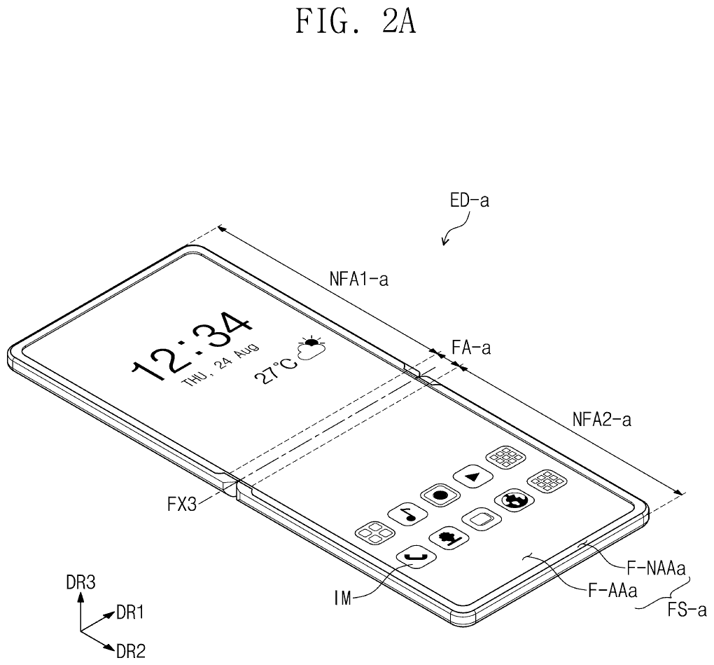

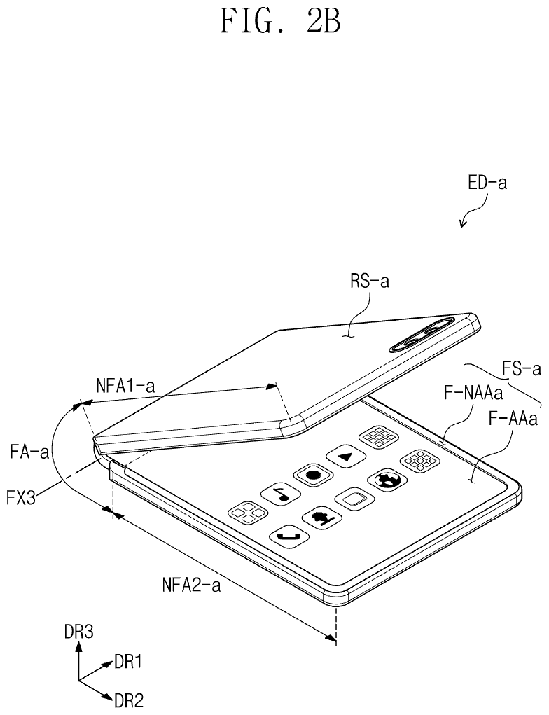

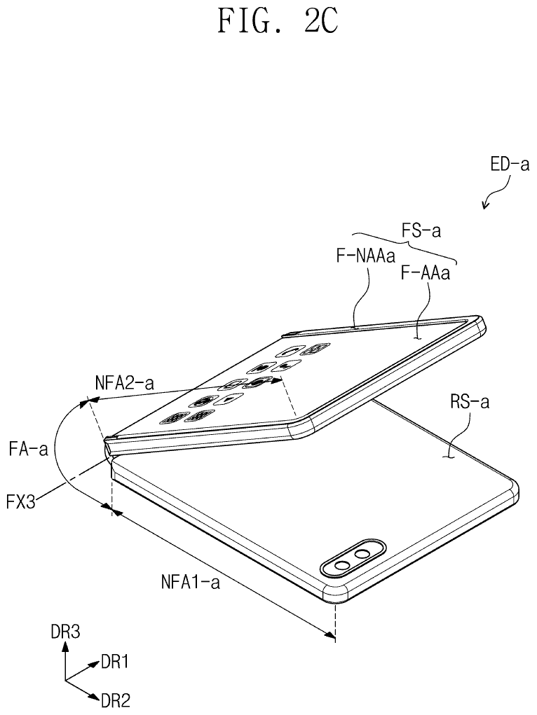

FIG. 1A is a perspective view illustrating an unfolded state of the electronic device ED. The electronic device ED in an embodiment may be a device activated depending on an electrical signal. In an embodiment, the electronic device ED may be a mobile phone, a tablet computer, a car navigation unit, a game machine, or a wearable device. However, the disclosure is not limited thereto. FIGS. 1A to 2C illustrate foldable electronic devices ED and ED-a. The foldable electronic devices ED and ED-a in embodiments may be mobile phones.

The electronic device ED may include a first display surface FS defined by a first directional axis DR1 and a second directional axis DR2 crossing the first directional axis DR1. The electronic device ED may provide an image IM to a user through the first display surface FS. The electronic device ED may display the image IM in the direction of a third directional axis DR3 on the first display surface FS parallel to the first directional axis DR1 and the second directional axis DR2.

In this specification, the first directional axis DR1 and the second directional axis DR2 may be orthogonal to each other, and the third directional axis DR3 may face in a normal direction to a plane defined by the first directional axis DR1 and the second directional axis DR2. The thickness direction of the electronic device ED may be a direction parallel to the third directional axis DR3. A front surface (or, an upper surface) and a rear surface (or, a lower surface) may be opposite each other in the direction of the third directional axis DR3, and normal directions of the front surface (or, the upper surface) and the rear surface (or, the lower surface) may be parallel to the third directional axis DR3. The front surface (or, the upper surface) refers to a surface close to the first display surface FS, and the rear surface (or, the lower surface) refers to a surface opposite the first display surface FS. In addition, the rear surface (or, the lower surface) refers to a surface close to a second display surface RS that will be described below. An upper side refers to a direction toward the first display surface FS, and a lower side refers to a direction away from the first display surface FS.

Sections of components are parallel to a direction of the third directional axis (hereinafter, also referred to as a third direction) DR3 that is the thickness direction, and a plane is perpendicular to the third direction DR3 that is the thickness direction. The plane refers to the plane defined by the first directional axis DR1 and the second directional axis DR2.

The directions indicated by the first to third directional axes DR1, DR2, and DR3 described in this specification may be relative concepts and may be converted to other directions. In addition, the directions indicated by the first to third directional axes DR1, DR2, and DR3 may be described as first to third directions, and identical reference numerals may be used to refer to the first to third directions.

The electronic device ED may sense an external input applied from the outside. The external input may include various forms of inputs provided from outside the electronic device ED. In an embodiment, the external input may include not only contact by a part of the user's body, such as the user's hand, but also an external input (e.g., hovering) that is applied in proximity to the electronic device ED or applied next (adjacent) to the electronic device ED at a predetermined distance. In addition, the external input may have various forms such as force, pressure, temperature, light, or the like.

The electronic device ED may include the first display surface FS and the second display surface RS. The first display surface FS may include a first active area F-AA, a first peripheral area F-NAA, and an electronic module area EMA. The second display surface RS may be defined as a surface opposite at least a portion of the first display surface FS. That is, the second display surface RS may be defined as a portion of the rear surface of the electronic device ED.

The first active area F-AA may be an area activated depending on an electrical signal. The first active area F-AA may be an area on which the image IM is displayed and that senses various forms of external inputs.

The first peripheral area F-NAA may be an area on which the image IM is not displayed. The first peripheral area F-NAA may be next (adjacent) to the first active area F-AA. The first peripheral area F-NAA may have a predetermined color. The first peripheral area F-NAA may surround the first active area F-AA. Accordingly, the shape of the first active area F-AA may be substantially defined by the first peripheral area F-NAA. However, this is illustrative, and the first peripheral area F-NAA may be disposed next (adjacent) to only one side of the first active area F-AA, or may be omitted.

Various electronic modules may be disposed in the electronic module area EMA. In an embodiment, the electronic modules may include at least one of a camera, a speaker, a light detection sensor, or a heat detection sensor, for example. The electronic module area EMA may sense an external object received through the display surfaces FS and RS, or may provide a sound signal, such as a voice, to the outside through the display surfaces FS and RS. The electronic modules may include a plurality of components and are not limited to a particular embodiment.

The electronic module area EMA may be surrounded by the first peripheral area F-NAA. However, this is illustrative, and the disclosure is not limited to a particular embodiment. In an embodiment, the electronic module area EMA may be surrounded by the first active area F-AA and the first peripheral area F-NAA. The electronic module area EMA may be disposed in the first active area F-AA.

The electronic device ED in an embodiment may be divided into at least one folding area FA and a plurality of non-folding areas NFA1 and NFA2 extending from the folding area FA. In an embodiment, the first non-folding area NFA1, the folding area FA, and the second non-folding area NFA2 arranged in a direction of the second directional axis (hereinafter, also referred to as a second direction) DR2 may be defined. The first non-folding area NFA1 and the second non-folding area NFA2 may be spaced apart from each other in the second direction DR2 with the folding area FA therebetween. In an embodiment, the first non-folding area NFA1 may be disposed on one side of the folding area FA in the second direction DR2, and the second non-folding area NFA2 may be disposed on an opposite side of the folding area FA in the second direction DR2, for example.

Although FIGS. 1A to 1D illustrate an embodiment of the electronic device ED including one folding area FA, the disclosure is not limited thereto, and a plurality of folding areas may be defined in the electronic device ED. In an embodiment, the electronic device ED in an embodiment may include two or more folding areas and three or more non-folding areas spaced apart from each other with the folding areas therebetween, for example.

FIG. 1B is a perspective view illustrating an embodiment of a folding operation of the electronic device ED. FIG. 1C is a plan view illustrating an embodiment of a folded state of the electronic device ED. FIG. 1D is a perspective view illustrating an embodiment of a folding operation of the electronic device ED.

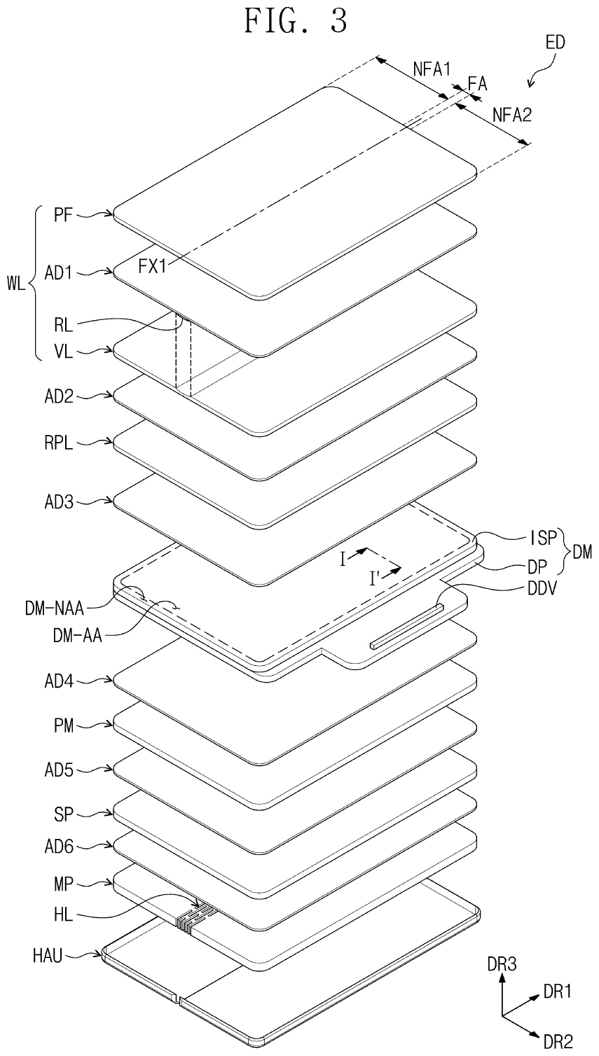

Referring to FIG. 1B, the electronic device ED in an embodiment may be folded about a first folding axis FX1 extending in the first direction DR1. The folding area FA may have a predetermined curvature and a predetermined radius of curvature in the folded state of the electronic device ED. In this embodiment, the first folding axis FX1 may be defined as being disposed above the upper surface of a window WL (refer to FIG. 3). The electronic device ED may be folded about the first folding axis FX1 and may be changed to an in-folded state in which the first non-folding area NFA1 and the second non-folding area NFA2 face each other and the first display surface FS is not exposed to the outside. In the embodiment, in a first mode, the electronic device ED may be folded in an in-folding manner such that the upper surfaces of the window WL that overlap the first non-folding area NFA1 and the second non-folding area NFA2 face each other, and in a second mode, the electronic device ED may be unfolded as illustrated in FIG. 1A.

Referring to FIG. 1C, the second display surface RS may be visible to the user when the electronic device ED in an embodiment is in the in-folded state. In this case, the second display surface RS may include a second active area R-AA that displays an image. The second active area R-AA may be an area activated depending on an electrical signal. The second active area R-AA may be an area on which an image is displayed and that senses various forms of external inputs.

The second display surface RS may include a second peripheral area R-NAA. The second peripheral area R-NAA may be next (adjacent) to the second active area R-AA. The second peripheral area R-NAA may have a predetermined color. The second peripheral area R-NAA may surround the second active area R-AA. Although not illustrated, the electronic device ED may further include, on the second display surface RS, an electronic module area in which an electronic module including various components is disposed, and the disclosure is not limited to a particular embodiment.

In an embodiment, when the electronic device ED is in the in-folded state, the distance between the first non-folding area NFA1 and the second non-folding area NFA2 may be smaller than the radius of a circle defined by the radius of curvature of the folding area FA. In this case, the folding area FA may be folded in a dumbbell shape, and the first non-folding area NFA1 and the second non-folding area NFA2 may be closer to each other. Accordingly, the slimmer electronic device ED may be provided in the folded state.

Referring to FIG. 1D, the electronic device ED in an embodiment may be folded about a second folding axis FX2 extending in the first direction DR1. In this embodiment, the second folding axis FX2 may be defined as being disposed below the rear surface of a support plate SP (refer to FIG. 3). The electronic device ED may be folded about the second folding axis FX2 and may be changed to an out-folded state such that the first display surface FS is exposed to the outside. In the embodiment, in the first mode, the electronic device ED may be folded in an out-folding manner such that the rear surfaces of a display panel DP (refer to FIG. 3) that overlap the first non-folding area NFA1 and the second non-folding area NFA2 face each other, and in the second mode, the electronic device ED may be unfolded as illustrated in FIG. 1A.

In FIGS. 1A to 1D, the electronic device ED is illustrated as being folded about one folding axis FX1 or FX2. However, the number of folding axes and the number of non-folding areas depending on the number of folding axes are not limited thereto. In an embodiment, the electronic device ED may be folded about a plurality of folding axes such that a portion of the first display surface FS and a portion of the second display surface RS face each other, for example. In addition, although the first and second folding axes FX1 and FX2 are illustrated as being parallel to the long sides of the electronic device ED, the disclosure is not limited thereto, and the first and second folding axes FX1 and FX2 may be parallel to the short sides of the electronic device ED.

In the electronic device ED, the first non-folding area NFA1 and the second non-folding area NFA2 may be defined as portions having the display surfaces FS and RS parallel to the plane defined by the first directional axis DR1 and the second directional axis DR2 in the state in which the electronic device ED is folded as illustrated in FIG. 1C, and the folding area FA may be defined as an area between the first non-folding area NFA1 and the second non-folding area NFA2. The folding area FA may include a curved portion having a predetermined curvature in the folded state.

FIG. 2A is a perspective view illustrating an embodiment of an electronic device. FIG. 2B is a perspective view illustrating the electronic device. FIG. 2C is a perspective view illustrating an embodiment of the electronic device.

FIGS. 2A to 2C are perspective views illustrating the electronic device ED-a according to the disclosure. FIG. 2A is a perspective view illustrating an unfolded state of the electronic device ED-a. FIGS. 2B and 2C are perspective views illustrating folding operations of the electronic device ED-a. FIG. 2B is a perspective view illustrating an in-folding operation of the electronic device ED-a illustrated in FIG. 2A. FIG. 2C is a perspective view illustrating an out-folding operation of the electronic device ED-a illustrated in FIG. 2A. FIG. 2A may be a view illustrating the electronic device ED-a in the second mode.

Referring to FIG. 2A, the electronic device ED-a may be folded about a third folding axis FX3 extending in the first direction DR1. The extension direction of the third folding axis FX3 may be parallel to the extension direction of the short sides of the electronic device ED-a.

The electronic device ED-a may be divided into a folding area FA-a, a first non-folding area NFA1-a next (adjacent) to one side of the folding area FA-a, and a second non-folding area NFA2-a next (adjacent) to an opposite side of the folding area FA-a. The first non-folding area NFA1-a and the second non-folding area NFA2-a may be spaced apart from each other with the folding area FA-a therebetween.

The folding area FA-a may be an area that is folded about the third folding axis FX3. The folding area FA-a may have a predetermined curvature and a predetermined radius of curvature in a folded state of the electronic device ED-a. The electronic device ED-a may be folded in an in-folding manner such that the first non-folding area NFA1-a and the second non-folding area NFA2-a face each other and a display surface FS-a is not exposed to the outside.

Referring to FIG. 2A, in an embodiment, the display surface FS-a of the electronic device ED-a may be visible to the user in the unfolded state (the second mode). As described with reference to FIGS. 1A to 1D, the display surface FS-a of the electronic device ED-a may include an active area F-AAa and a peripheral area F-NAAa. The active area F-AAa may be an area on which an image IM is displayed and that senses various forms of external inputs.

Referring to FIG. 2B, the rear surface RS-a may be visible to the user when the electronic device ED-a of an embodiment is in an in-folded state. In an embodiment, the rear surface RS-a may function as a second display surface on which a video or image is displayed. In addition, the electronic device ED-a may include, on the rear surface RS-a, an electronic module area in which an electronic module including various components is disposed. In an embodiment, an active area on which an image is displayed may be further included in the rear surface RS-a of the electronic device ED-a.

Referring to FIG. 2C, the electronic device ED-a may be folded about the third folding axis FX3 and may be changed to an out-folded state in which one area of the rear surface RS-a that overlaps the first non-folding area NFA1-a and an opposite area of the rear surface RS-a that overlaps the second non-folding area NFA2-a face each other.

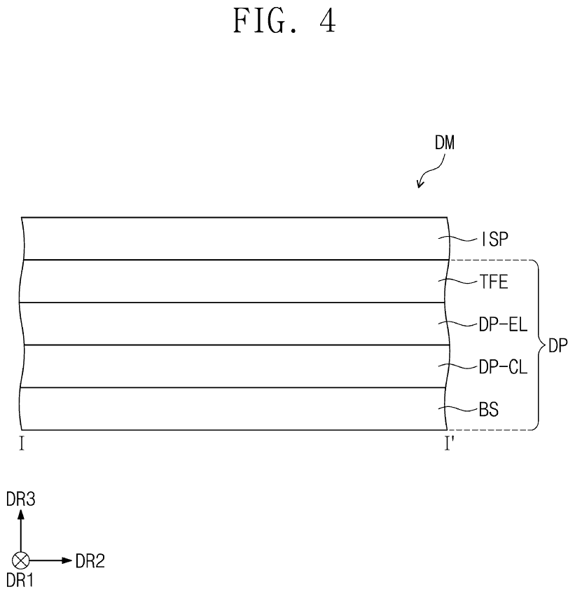

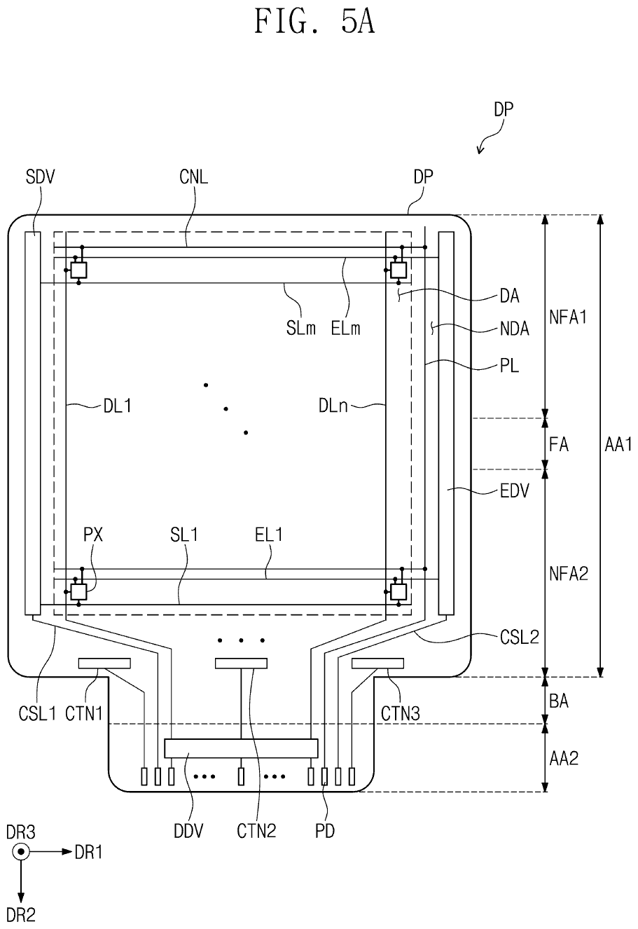

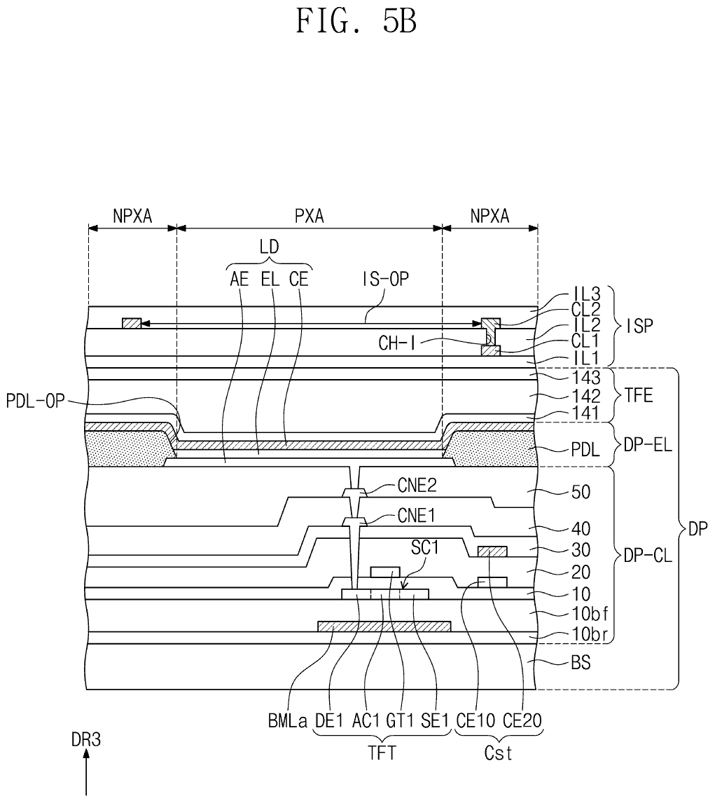

FIG. 3 is an exploded perspective view illustrating an embodiment of the electronic device ED. FIG. 4 is a cross-sectional view illustrating an embodiment of a portion corresponding to line I-I′ of FIG. 3. FIG. 5A is a plan view of the display panel DP. FIG. 5B is a cross-sectional view of the electronic device ED.

FIG. 3 is an exploded perspective view illustrating an embodiment of the electronic device ED. FIG. 4 is a cross-sectional view illustrating a portion corresponding to line I-I′ of FIG. 3. FIG. 5A is a plan view of an embodiment of the display panel. Features of the electronic device ED that will be described below may be applied to the electronic device ED-a described with reference to FIGS. 2A to 2C.

Referring to FIG. 3, the electronic device ED may include the window WL, an optical layer RPL, a display module DM, a lower film PM, the support plate SP, a lower plate MP, and a housing HAU.

The housing HAU may be coupled with the window WL to define the exterior of the electronic device ED. The housing HAU may include a material having a relatively high rigidity. In an embodiment, the housing HAU may include a plurality of frames and/or support plates including or consisting of glass, plastic, or metal. The housing HAU may provide a receiving space. The display module DM may be accommodated in the receiving space and may be protected from external impact. In an embodiment, the electronic device ED may further include, in the housing HAU overlapping the folding area FA, a hinge structure for guiding a folding operation of the electronic device ED.

The display module DM may be disposed under the optical layer RPL. The display module DM may be activated depending on an electrical signal. The display module DM may be activated to display the image IM (refer to FIG. 1A) on the active area F-AA (refer to FIG. 1A) of the electronic device ED. A display area DM-AA and a non-display area DM-NAA may be defined in the display module DM. The display area DM-AA may be an area activated depending on an electrical signal. The non-display area DM-NAA may be an area disposed next (adjacent) to at least one side of the display area DM-AA. A circuit or wiring for driving the display area DM-AA may be disposed in the non-display area DM-NAA.

The optical layer RPL may be disposed between the display module DM and the window WL. The optical layer RPL may be an anti-reflective layer that decreases the reflectance of external light incident from outside the display module DM. The optical layer RPL may be formed on the display module DM through a continuous process. The optical layer RPL may include a polarizing plate or a color filter layer. In an embodiment, the optical layer RPL may include at least one of a phase retarder, a polarizer, a polarizing film, or a polarizing filter. In an alternative embodiment, the optical layer RPL may include a plurality of color filters arranged in a predetermined arrangement and a black matrix next (adjacent) to the color filters.

The image IM (refer to FIG. 1A) generated by the display module DM may be provided to the user through the window WL. The window WL may include a polymer substrate or a glass substrate.

The window WL in an embodiment may include a protective layer PF, a base substrate VL, and a resin layer RL. The protective layer PF and the base substrate VL may include an optically clear insulating material.

The protective layer PF may be disposed on the base substrate VL. The protective layer PF may be a functional layer that protects the upper surface of the base substrate VL. The protective layer PF may include a polymer film. The protective layer PF may include an anti-fingerprint coating agent, a hard coating agent, or an anti-static agent.

The resin layer RL may overlap the folding area FA and may be disposed between a first adhesive layer (also referred to as a window adhesive layer) AD1 and the base substrate VL. An arrangement relationship between the protective layer PF, the base substrate VL, and the resin layer RL will be described below.

The lower film PM may protect a lower portion of the display panel DP. The lower film PM may include a flexible plastic material. In an embodiment, the lower film PM may include polyethylene terephthalate, for example.

The support plate SP may be disposed under the display panel DP. A portion of the support plate SP according to the disclosure may be bent to absorb impact applied between components disposed on the support plate SP and the housing HAU. In addition, the support plate SP may prevent infiltration of foreign matter into the components disposed on the support plate SP.

The lower plate MP may be disposed under the support plate SP. To facilitate a folding operation of the electronic device ED, the lower plate MP may include a plurality of holes HL that overlap the folding area and penetrate the lower plate MP. The lower plate MP may include metal. In an embodiment, the lower plate MP may include at least one of aluminum (Al) or molybdenum (Mo), for example. However, without being limited thereto, the lower plate MP may include a matrix including a filler and woven fiber lines disposed inside the matrix. The fiber lines may be arranged in a fabric form inside the matrix.

The fiber lines may include a fiber reinforced composite. The fiber reinforced composite may be one of carbon fiber-reinforced plastic (“CFRP”) and glass fiber-reinforced plastic (“GFRP”). The diameter of one strand of fiber included in one fiber line may range from 3 micrometers (μm) to 10 μm.

The matrix in an embodiment may include at least one of epoxy, polyester, polyamide, polycarbonate, polypropylene, polybutylene, or vinyl ester.

The matrix may include the filler. The filler may include at least one of silica, barium sulphate, sintered talc, barium titanate, titanium oxide, clay, alumina, mica, boehmite, zinc borate, or zinc titanate.

The electronic device ED in an embodiment may further include at least one of a cushion layer or a shielding layer. The cushion layer may prevent the lower plate MP from being pressed and plastically deformed by external impact and force. The cushion layer may include an elastomer such as a sponge, expanded foam, or a urethane resin. Furthermore, the cushion layer may include at least one of an acrylic polymer, a urethane-based polymer, a silicone-based polymer, and an imide-based polymer. The shielding layer may be an EMI shielding layer or a heat radiating layer.

The electronic device ED in an embodiment may further include first to sixth adhesive layers AD1 to AD6. The first adhesive layer AD1 may be disposed between the base substrate VL and the protective layer PF. The second adhesive layer AD2 may be disposed between the optical layer RPL and the base substrate VL. The third adhesive layer AD3 may be disposed between the display module DM and the optical layer RPL. The fourth adhesive layer AD4 may be disposed between the lower film PM and the display module DM. The fifth adhesive layer AD5 may be disposed between the support plate SP and the lower film PM. The sixth adhesive layer AD6 may be disposed between the lower plate MP and the support plate SP.

Each of the first to sixth adhesive layers AD1 to AD6 and adhesive layers that will be described below may include a conventional adhesive, such as a pressure sensitive adhesive (“PSA”), an optically clear adhesive (“OCA”), or an optical clear resin (“OCR”), and is not limited to a particular embodiment. In the electronic device ED in an embodiment, at least one of the first to sixth adhesive layers AD1 to AD6 may be omitted.

Referring to FIG. 4, the display module DM may include the display panel DP and an input sensing layer ISP disposed on the display panel DP. The display panel DP may be a component that substantially generates an image. The display panel DP may be an emissive display panel. In an embodiment, the display panel DP may be an organic light emitting display panel, an inorganic light emitting display panel, a micro-light-emitting diode (“micro-LED”) display panel, a micro-organic LED (“micro-OLED”) display panel, or a nano-LED display panel, for example.

The display panel DP may include a base layer BS, a circuit layer (also referred to as circuit element layer) DP-CL, a display element layer DP-EL, and an encapsulation layer TFE sequentially stacked one above another. Unlike that illustrated in FIG. 4, a functional layer may be additionally disposed between two next (adjacent) layers among the base layer BS, the circuit layer DP-CL, the display element layer DP-EL, and the encapsulation layer TFE.

The base layer BS may provide a base surface on which the circuit layer DP-CL is disposed. The base layer BS may be a flexible substrate that is able to be bent, folded, or rolled. The base layer BS may be a glass substrate, a metal substrate, or a polymer substrate. However, the disclosure is not limited thereto, and the base layer BS may include an inorganic layer, an organic layer, or a composite layer.

The base layer BS may include a single layer or multiple layers. In an embodiment, the base layer BS may include a first synthetic resin layer, an inorganic layer having a multi-layer structure or a single-layer structure, and a second synthetic resin layer disposed on the inorganic layer having the multi-layer structure or the single-layer structure, for example. Each of the first synthetic resin layer and the second synthetic resin layer may include a polyimide-based resin. In an alternative embodiment, each of the first synthetic resin layer and the second synthetic resin layer may include at least one of an acrylic resin, a methacrylic resin, a polyisoprene resin, a vinyl resin, an epoxy resin, a urethane-based resin, a cellulosic resin, a siloxane-based resin, a polyamide resin, and a perylene-based resin. In this specification, a “XX”-based resin refers to a resin including a “XX” functional group where “XX” denotes a chemical component.

The circuit layer DP-CL may be disposed on the base layer BS. The circuit layer DP-CL may include an insulating layer, a semiconductor pattern, a conductive pattern, and a signal line. The display element layer DP-EL may be disposed on the circuit layer DP-CL. The display element layer DP-EL may include a light emitting element LD (refer to FIG. 5B). In an embodiment, the light emitting element may include an organic luminescent material, an inorganic luminescent material, an organic-inorganic luminescent material, a quantum dot, a quantum rod, a micro-LED, or a nano-LED, for example.

The encapsulation layer TFE may be disposed on the display element layer DP-EL. The encapsulation layer TFE may protect the display element layer DP-EL from foreign matter such as moisture, oxygen, and dust particles. The encapsulation layer TFE may include at least one inorganic layer. In an embodiment, the encapsulation layer TFE may include an inorganic layer, an organic layer, and an inorganic layer sequentially stacked one above another, for example.

The input sensing layer ISP may be disposed on the display panel DP. The input sensing layer ISP may be directly disposed on the encapsulation layer TFE. In an alternative embodiment, an adhesive member may be disposed between the input sensing layer ISP and the display panel DP.

In this specification, when one component is directly disposed on another component, this means that a third component is not disposed between the one component and the other component. That is, when the one component is “directly disposed” on the other component, this means that the one component “contacts” the other component.

The input sensing layer ISP may sense an external input, may change the external input to a predetermined input signal, and may provide the input signal to the display panel DP. In an embodiment, the input sensing layer ISP may be a touch sensing layer that senses a touch. The input sensing layer ISP may recognize a direct touch of the user, an indirect touch of the user, a direct touch of an object, or an indirect touch of the object.

The input sensing layer ISP may sense at least one of the position of a touch applied from the outside or the intensity (pressure) of the touch. The input sensing layer ISP may have various structures or may include or consist of various materials. However, the input sensing layer ISP is not limited to a particular embodiment. In an embodiment, the input sensing layer ISP may sense an external input in a capacitance type. The display panel DP may receive an input signal from the input sensing layer ISP and may generate an image corresponding to the input signal.

Referring to FIG. 5A, the display panel DP may include pixels PX, a scan driver SDV, a data driver DDV, and an emission driver EDV.

The display panel DP may include a first area AA1, a second area AA2, and a bending area BA between the first area AA1 and the second area AA2. The bending area BA may extend in the first direction DR1, and the first area AA1, the bending area BA, and the second area AA2 may be arranged in the second direction DR2. The bending area BA may be bent about a bending axis extending in the first direction DR1 such that the second area AA2 overlaps the lower surface of the first area AA1. In an embodiment, the widths of the bending area BA and the second area AA2 in the first direction DR1 may be smaller than the width of the first area AA1 in the first direction DR1. Accordingly, the bending area BA may be easily bent to the lower surface of the first area AA1.

The first area AA1 may include a display area DA and a non-display area NDA around the display area DA. The non-display area NDA may surround the display area DA. The display area DA may be an area that displays an image, and the non-display area NDA may be an area that does not display an image. The second area AA2 and the bending area BA may be areas that do not display an image.

The first area AA1 may include a first non-folding area NFA1, a second non-folding area NFA2, and a folding area FA between the first non-folding area NFA1 and the second non-folding area NFA2. The first non-folding area NFA1, the folding area FA, and the second non-folding area NFA2 may be arranged in the second direction DR2. The first and second non-folding areas NFA1 and NFA2 and the folding area FA may correspond to the first and second non-folding areas NFA1 and NFA2 and the folding area FA of the electronic device ED illustrated in FIG. 1A.

The first area AA1 may be bent and folded about the above-described folding axes. In an embodiment, the folding area FA of the first area AA1 may be folded about the above-described folding axes, and the display panel DP may be folded accordingly, for example.

The display panel DP may include the plurality of pixels PX, a plurality of scan lines SL1 to SLm, a plurality of data lines DL1 to DLn, a plurality of emission lines EL1 to ELm, first and second control lines CSL1 and CSL2, a power line PL, a plurality of connecting lines CNL, and a plurality of pads PD. Here, “m” and “n” are natural numbers. The pixels PX may be disposed in the display area DA and may be connected to the scan lines SL1 to SLm, the data lines DL1 to DLn, and the emission lines EL1 to ELm.

The scan driver SDV and the emission driver EDV may be disposed in the non-display area NDA. The scan driver SDV and the emission driver EDV may be disposed in the non-display areas NDA next (adjacent) to opposite sides of the first area AA1 that face away from each other in the second direction DR2. The data driver DDV may be disposed in the second area AA2. The data driver DDV may be manufactured in the form of an integrated circuit chip and may be disposed (e.g., mounted) on the second area AA2.

The scan lines SL1 to SLm may extend in the second direction DR2 and may be connected to the scan driver SDV. The data lines DL1 to DLn may extend in the first direction DR1 and may be connected to the data driver DDV via the bending area BA. The data driver DDV may be connected to the pixels PX through the data lines DL1 to DLn. The emission lines EL1 to ELm may extend in the second direction DR2 and may be connected to the emission driver EDV.

The power line PL may extend in the first direction DR1 and may be disposed in the non-display area NDA. The power line PL may be disposed between the display area DA and the emission driver EDV. The power line PL may extend to the second area AA2 via the bending area BA. The power line PL may extend toward the lower end of the second area AA2 when viewed from above the plane. The power line PL may receive a driving voltage.

The connecting lines CNL may extend in the second direction DR2 and may be arranged in the first direction DR1. The connecting lines CNL may be connected to the power line PL and the pixels PX. The driving voltage may be applied to the pixels PX through the power line PL and the connecting lines CNL connected with each other.

The first control line CSL1 may be connected to the scan driver SDV and may extend toward the lower end of the second area AA2 via the bending area BA. The second control line CSL2 may be connected to the emission driver EDV and may extend toward the lower end of the second area AA2 via the bending area BA. The data driver DDV may be disposed between the first control line CSL1 and the second control line CSL2.

The pads PD may be disposed next (adjacent) to the lower end of the second area AA2 when viewed from above the plane. The data driver DDV, the power line PL, the first control line CSL1, and the second control line CSL2 may be connected to the pads PD.

The data lines DL1 to DLn may be connected to the corresponding pads PD through the data driver DDV. In an embodiment, the data lines DL1 to DLn may be connected to the data driver DDV, and the data driver DDV may be connected to the pads PD corresponding to the data lines DL1 to DLn, for example.

Although not illustrated, a printed circuit board may be connected to the pads PD, and a timing controller and a voltage generator may be disposed on the printed circuit board. The timing controller may be manufactured in the form of an integrated circuit chip and may be disposed (e.g., mounted) on the printed circuit board. The timing controller and the voltage generator may be connected to the pads PD through the printed circuit board.

The timing controller may control operations of the scan driver SDV, the data driver DDV, and the emission driver EDV. The timing controller may generate a scan control signal, a data control signal, and an emission control signal in response to control signals received from the outside. The voltage generator may generate the driving voltage.

The scan control signal may be provided to the scan driver SDV through the first control line CSL1. The emission control signal may be provided to the emission driver EDV through the second control line CSL2. The data control signal may be provided to the data driver DDV. The timing controller may receive image signals from the outside, may convert the data format of the image signals according to the specification of an interface with the data driver DDV, and may provide the converted signals to the data driver DDV.

The scan driver SDV may generate a plurality of scan signals in response to the scan control signal. The scan signals may be applied to the pixels PX through the scan lines SL1 to SLm. The scan signals may be sequentially applied to the pixels PX.

The data driver DDV may generate a plurality of data voltages corresponding to the image signals in response to the data control signal. The data voltages may be applied to the pixels PX through the data lines DL1 to DLn. The emission driver EDV may generate a plurality of emission signals in response to the emission control signal. The emission signals may be applied to the pixels PX through the emission lines EL1 to ELm.

The pixels PX may receive the data voltages in response to the scan signals. The pixels PX may display an image by emitting light having luminance corresponding to the data voltages in response to the emission signals. The light emission time of the pixels PX may be controlled by the emission signals. Each of the pixels PX may include transistors, a capacitor, and a light emitting element connected to the transistors and the capacitor. Each of the transistors may include a semiconductor pattern. The semiconductor pattern may include poly silicon, amorphous silicon, or metal oxide. The semiconductor pattern may be doped with an N-type dopant or a P-type dopant. The semiconductor pattern may include highly-doped areas and a lightly-doped area. The highly-doped areas may have a higher conductivity than the lightly-doped area and may substantially serve as a source electrode and a drain electrode of the transistor. The lightly-doped area may substantially correspond to an active (or, channel) area of the transistor.

The display panel DP in an embodiment may define lower contact holes CTN1, CTN2, and CTN3 disposed in the non-display area NDA. The lower contact holes CTN1, CTN2, and CTN3 may be connected with upper contact holes CTN-1, CTN-2, and CTN-3 included in the input sensing layer ISP that will be described below.

FIG. 5B illustrates a cross-sectional view of the electronic device ED corresponding to one pixel PX among the pixels PX illustrated in FIG. 5A.

In FIG. 5B, a section of the electronic device ED that corresponds to one emissive area PXA and a non-emissive area NPXA around the one emissive area PXA is illustrated. Specifically, a section of the display panel DP and the input sensing layer ISP is illustrated in FIG. 5B.

The display panel DP is illustrated with respect to a light emitting element LD and a transistor TFT connected to the light emitting element LD. The transistor TFT may be one of a plurality of transistors included in a driving circuit of the pixel PX (refer to FIG. 5A). In this embodiment, the transistor TFT is described as a silicon transistor. However, the transistor TFT may be a metal oxide transistor.

A barrier layer 10br may be disposed on the base layer BS. The barrier layer 10br prevents infiltration of foreign matter from the outside. The barrier layer 10br may include at least one inorganic layer. The barrier layer 10br may include a silicon oxide layer and a silicon nitride layer. A plurality of silicon oxide layers and a plurality of silicon nitride layers may be provided. The silicon oxide layers and the silicon nitride layers may be alternately stacked one above another.

A shielding electrode BMLa may be disposed on the barrier layer 10br. The shielding electrode BMLa may include metal. The shielding electrode BMLa may include molybdenum (Mo) having good heat resistance, an alloy including or consisting of molybdenum (Mo), titanium (Ti), or an alloy including or consisting of titanium (Ti). The shielding electrode BMLa may receive a bias voltage.

The shielding electrode BMLa may prevent electrical potential due to polarization from affecting the silicon transistor. The shielding electrode BMLa may prevent external light from reaching the silicon transistor. In an embodiment of the disclosure, the shielding electrode BMLa may be a floating electrode isolated from another electrode or wiring.

A buffer layer 10bf may be disposed on the barrier layer 10br. The buffer layer 10bf may prevent diffusion of metal atoms or impurities from the base layer BS to a semiconductor pattern SC1 disposed over the base layer BS. The buffer layer 10bf may include at least one inorganic layer. The buffer layer 10bf may include a silicon oxide layer and a silicon nitride layer.

The semiconductor pattern SC1 may be disposed on the buffer layer 10bf. The semiconductor pattern SC1 may include a silicon semiconductor. In an embodiment, the silicon semiconductor may include amorphous silicon or polycrystalline silicon, for example. In an embodiment, the semiconductor pattern SC1 may include low-temperature poly silicon, for example.

The semiconductor pattern may include first areas having a relatively high conductivity and a second area having a relatively low conductivity. The first areas may be doped with an N-type dopant or a P-type dopant. A P-type transistor may include a doped area that is doped with a P-type dopant, and an N-type transistor may include a doped area that is doped with an N-type dopant. The second area may be an un-doped area, or may be an area more lightly doped than the first areas.

The first areas may have a higher conductivity than the second area and may substantially serve as electrodes or signal lines. The second area may substantially correspond to an active area (or, a channel) of the transistor. In other words, one portion of the semiconductor pattern may be the active area of the transistor, another portion may be a source or drain of the transistor, and a remaining (the other) portion may be a connecting electrode or a connecting signal line.

A source area (or, a source) SE1, an active area (or, a channel) AC1, and a drain area (or, a drain) DE1 of the transistor TFT may be formed from the semiconductor pattern. The source area SE1 and the drain area DE1 may extend from the active area AC1 in opposite directions on the section.

A first insulating layer 10 may be disposed on the buffer layer 10bf. The first insulating layer 10 may commonly overlap the plurality of pixels PX (refer to FIG. 5A) and may cover the semiconductor pattern. The first insulating layer 10 may include an inorganic layer and/or an organic layer and may have a single-layer structure or a multi-layer structure. The inorganic layer may include at least one of aluminum oxide, titanium oxide, silicon oxide, silicon nitride, silicon oxy nitride, zirconium oxide, or hafnium oxide. In this embodiment, the first insulating layer 10 may be a single silicon oxide layer. Not only the first insulating layer 10 but also insulating layers of the circuit layer DP-CL that will be described below may be inorganic layers and/or organic layers and may have a single-layer structure or a multi-layer structure. The inorganic layers may include at least one of the aforementioned materials, but are not limited thereto.

A gate GT1 of the transistor TFT is disposed on the first insulating layer 10. The gate GT1 may be a portion of a metal pattern. The gate GT1 overlaps the active area AC1. The gate GT1 may function as a mask in a process of doping the semiconductor pattern. The gate GT1 may include titanium (Ti), silver (Ag), an alloy including or consisting of silver, molybdenum (Mo), an alloy including or consisting of molybdenum, aluminum (Al), an alloy including or consisting of aluminum, aluminum nitride (AlN), tungsten (W), tungsten nitride (WN), copper (Cu), indium tin oxide (“ITO”), or indium zinc oxide (“IZO”), but is not particularly limited thereto.

A second insulating layer 20 may be disposed on the first insulating layer 10 and may cover the gate GT1. A third insulating layer 30 may be disposed on the second insulating layer 20. A second electrode CE20 of a storage capacitor Cst may be disposed between the second insulating layer 20 and the third insulating layer 30. In addition, a first electrode CE10 of the storage capacitor Cst may be disposed between the first insulating layer 10 and the second insulating layer 20.

A first connecting electrode CNE1 may be disposed on the third insulating layer 30. The first connecting electrode CNE1 may be connected to the drain area DE1 of the transistor TFT through a contact hole penetrating the first to third insulating layers 10, 20, and 30.

A fourth insulating layer 40 may be disposed on the third insulating layer 30. A second connecting electrode CNE2 may be disposed on the fourth insulating layer 40. The second connecting electrode CNE2 may be connected to the first connecting electrode CNE1 through a contact hole penetrating the fourth insulating layer 40. A fifth insulating layer 50 may be disposed on the fourth insulating layer 40 and may cover the second connecting electrode CNE2. The stacked structure of the first to fifth insulating layers 10, 20, 30, 40, and 50 is merely illustrative, and an additional conductive layer and an additional insulating layer may be further disposed in addition to the first to fifth insulating layers 10, 20, 30, 40, and 50.

Each of the fourth insulating layer 40 and the fifth insulating layer 50 may be an organic layer. In an embodiment, the organic layer may include a general purpose polymer such (“BCB”), polyimide, as benzocyclobutene hexamethyldisiloxane (“HMDSO”), Polymethylmethacrylate (“PMMA”), or Polystyrene (“PS”), a polymer derivative having a phenolic group, an acrylate-based polymer, an imide-based polymer, an aryl ether-based polymer, an amide-based polymer, a fluorine-based polymer, a p-xylene-based polymer, a vinyl alcohol-based polymer, or any combinations thereof, for example.

The light emitting element LD may include a first electrode (or an anode or a pixel electrode) AE, an emissive layer EL, and a second electrode (or a cathode or a common electrode) CE. The first electrodes AE may be disposed on the fifth insulating layer 50. The first electrode AE may be connected to the second connecting electrode CNE20 through a contact hole penetrating the fifth insulating layer 50.

However, without being limited thereto, the second connecting electrode CNE2 may be connected to the second electrode CE. In this case, the first electrode AE (or, the anode) may correspond to a common electrode, and the second electrode CE (or, the cathode) may be separated for each of the emissive areas PXA-B, PXA-R, and PXA-G in FIG. 3A. Furthermore, even though the light emitting element LD has the structure illustrated in FIG. 5B, the first electrode AE may be a cathode, and the second electrode CE may be an anode (an inverted structure).

The first electrode AE may be a transparent electrode, a translucent electrode, or a reflective electrode. The first electrodes AE may include a reflective layer including or consisting of Ag, Mg, Al, Pt, Pd, Au, Ni, Nd, Ir, Cr, or any combinations thereof and a transparent or translucent electrode layer formed on the reflective layer. The transparent or translucent electrode layer may include at least one selected from the group including or consisting of indium tin oxide (“ITO”), indium zinc oxide (“IZO”), indium gallium zinc oxide (“IGZO”), zinc oxide (ZnO), or indium oxide (In2IO3) and aluminum-doped zinc oxide (“AZO”). In an embodiment, the first electrode AE may include a stacked structure of ITO/Ag/ITO, for example.

A pixel defining layer PDL may be disposed on the fifth insulating layer 50. The pixel defining layer PDL may be an organic layer. In an embodiment of the disclosure, the pixel defining layer PDL may have a property of absorbing light. In an embodiment, the pixel defining layer PDL may be black in color, for example. The pixel defining layer PDL may include a black coloring agent. The black coloring agent may include a black dye or a black pigment. The black coloring agent may include carbon black, metal such as chromium, or oxide thereof. The pixel defining layer PDL may correspond to a light blocking pattern having light blocking characteristics.

The pixel defining layer PDL may cover a portion of the first electrode AE. In an embodiment, a light emitting opening PDL-OP for exposing a portion of the first electrode AE may be defined in the pixel defining layer PDL, for example. The light emitting opening PDL-OP may define the emissive area PXA of the display panel DP.

In an embodiment, a hole control layer may be disposed between the first electrode AE and the emissive layer EL. The hole control layer may include a hole transport layer and may further include a hole injection layer. An electron control layer may be disposed between the emissive layer EL and the second electrode CE. The electron control layer may include an electron transport layer and may further include an electron injection layer.

The encapsulation layer TFE may be disposed on the display element layer DP-EL. The encapsulation layer TFE may include an inorganic layer 141, an organic layer 142, and an inorganic layer 143 sequentially stacked one above another. However, layers constituting the encapsulation layer TFE are not limited thereto.

The inorganic layers 141 and 143 may protect the display element layer DP-EL from moisture and oxygen, and the organic layer 142 may protect the display element layer DP-EL from foreign matter such as dust particles. The inorganic layers 141 and 143 may include a silicon nitride layer, a silicon oxy nitride layer, a silicon oxide layer, a titanium oxide layer, or an aluminum oxide layer. The organic layer 142 may include an acrylic organic layer, but is not limited thereto.

The input sensing layer ISP may include a first sensing insulation layer IL1, a first conductive pattern layer CL1, a second sensing insulation layer IL2, a second conductive pattern layer CL2, and a third sensing insulation layer IL3. The first sensing insulation layer IL1 may be directly disposed on the encapsulation layer TFE.

In an embodiment of the disclosure, the first sensing insulation layer IL1 and/or the third sensing insulation layer IL3 may be omitted. When the first sensing insulation layer IL1 is omitted, the first conductive pattern layer CL1 may be directly disposed on the uppermost insulating layer of the encapsulation layer TFE.

The first conductive pattern layer CL1 may include a first conductive pattern, and the second conductive pattern layer CL2 may include a second conductive pattern. Each of the first conductive pattern and the second conductive pattern may include regularly arranged patterns. Hereinafter, the first conductive pattern layer CL1 and the first conductive pattern refer to the same reference numeral, and the second conductive pattern layer CL2 and the second conductive pattern refer to the same reference numeral.

Each of the first conductive pattern CL1 and the second conductive pattern CL2 may have a single layer structure, or may have a multi-layer structure stacked along the third directional axis DR3. A conductive pattern having a multi-layer structure may include at least two of transparent conductive layers and metal layers. The multi-layered conductive layer may include metal layers including or consisting of different metals. The transparent conductive layers may include indium tin oxide (“ITO”), indium zinc oxide (“IZO”), zinc oxide (ZnO), indium tin zinc oxide (“ITZO”), poly(3,4-ethylenedioxythiophene) (“PEDOT”), metal nano-wire, or graphene. The metal layers may include molybdenum, silver, titanium, copper, aluminum, and any alloys thereof.

The first conductive pattern CL1 and the second conductive pattern CL2 overlap the pixel defining layer PDL. In an embodiment, the second conductive pattern CL2 may contact the first conductive pattern CL1 through an opening CH-I defined in the second sensing insulation layer IL2. An opening IS-OP corresponding to the emissive area PXA may be defined in the second conductive pattern CL2. The opening IS-OP may have a larger area than that of the emissive area PXA.

In this embodiment, each of the first to third sensing insulation layers IL1, IL2, and IL3 may include an inorganic layer or an organic layer. In this embodiment, each of the first to third sensing insulation layers IL1, IL2, and IL3 may include an inorganic layer. The inorganic layer may include silicon oxide, silicon nitride, or silicon oxy nitride.

In an embodiment of the disclosure, at least one of the first to third sensing insulation layers IL1, IL2, and IL3 may be an organic layer. In an embodiment, the third sensing insulation layer IL3 may include an organic layer, for example. The organic layer may include at least one of an acrylic resin, a methacrylic resin, a polyisoprene resin, a vinyl resin, an epoxy resin, a urethane-based resin, a cellulosic resin, a siloxane-based resin, a polyimide resin, a polyamide resin, or a perylene-based resin.

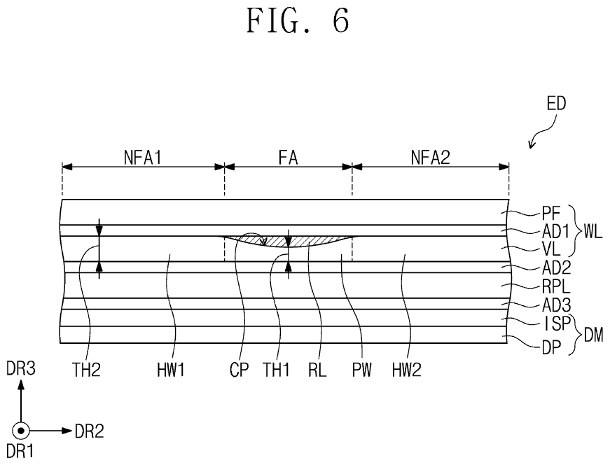

FIG. 6 is a cross-sectional view of an embodiment of the electronic device according to the disclosure. In FIG. 6, only the window and the optical layer RPL disposed under the window among the components included in the electronic device are illustrated, and the remaining components described with reference to FIG. 3 are omitted. Furthermore, the window described with reference to FIG. 6 may be applied to the electronic devices ED and ED-a in FIGS. 1A to 2C.

Referring to FIG. 6, the electronic device ED in an embodiment may include the window WL and the optical layer RPL disposed under the window WL. The window WL and the optical layer RPL may be coupled by the second adhesive layer AD2.

The window WL in an embodiment may include the protective layer PF and the base substrate VL. The protective layer PF and the base substrate VL may be coupled by the first adhesive layer AD1. In the embodiment, the upper surface of the base substrate VL may contact the first adhesive layer AD1, and the lower surface of the base substrate VL may contact the second adhesive layer AD2.

The base substrate VL may include a first flat area HW1 overlapping the first non-folding area NFA1, a second flat area HW2 overlapping the second non-folding area NFA2, and a pattern area PW overlapping the folding area FA.

The pattern area PW may include an area CP recessed in the direction from the protective layer PF to the base substrate VL. In the embodiment, the area (also referred to as a recessed area) CP may have a concave shape on the section along the first direction DR1. The first adhesive layer AD1 may fill the recessed area CP.

According to the disclosure, the base substrate VL may include a transparent resin. The transparent resin of which the base substrate VL is formed may be a high-viscosity resin. The resin used to form the base substrate VL may have a viscosity of 1000 centipoise (cP) to 2500 cP. The modulus of the base substrate VL may range from 0.5 5 gigapascal (GPa) to 2 GPa, and the crack strain of the base substrate VL may range from 2% to 15%.

According to the disclosure, the minimum thickness TH1 of the pattern area PW may range from 10 μm to 40 μm. The thickness TH2 of the first flat area HW1 and the second flat area HW2 may range from 50 μm to 100 μm.

Since the base substrate VL constituting the window WL includes the transparent resin according to the disclosure, the manufacturing cost of the window WL may be reduced. In addition, since the pattern area PW overlapping the folding area FA has a variable thickness, the base substrate VL may be prevented from being cracked in a folding operation of the electronic device ED. Accordingly, the electronic device ED with improved folding may be provided.

FIG. 6 is a cross-sectional view of an embodiment of the electronic device.

Among the components of the electronic device ED described with reference to FIG. 3, only the window WL, the optical layer RPL, the display module DM, and the first to third adhesive layers AD1 to AD3 are illustrated in FIG. 6.

The electronic device ED in an embodiment may include the window WL and the optical layer RPL disposed under the window WL. The window WL and the optical layer RPL may be coupled by the second adhesive layer AD2.

The window WL may include the protective layer PF, the base substrate VL, and the resin layer RL. The resin layer RL may be disposed between the protective layer PF and the base substrate VL, and the protective layer PF and the base substrate VL may be coupled by the first adhesive layer AD1. In the embodiment, the upper surface of the base substrate VL may contact the first adhesive layer AD1, and the lower surface of the base substrate VL may contact the second adhesive layer AD2.

The base substrate VL may include the first flat area HW1 overlapping the first non-folding area NFA1, the second flat area HW2 overlapping the second non-folding area NFA2, and the pattern area PW overlapping the folding area FA.

The pattern area PW may define the area CP recessed in the direction from the protective layer PF to the base substrate VL. In the embodiment, the recessed area CP may have a concave shape on the section along the first direction DR1. According to the disclosure, the minimum thickness TH1 of the pattern area PW may range from 10 μm to 40 μm. The thickness TH2 of the first flat area HW1 and the second flat area HW2 may range from 50 μm to 100 μm.

Since the recessed area CP has a concave shape in the illustrative embodiment, the thickness of the pattern area PW may be decreased in the direction from the boundaries PW between the pattern area PW and the first and second flat areas HW1 and HW2 to the center of the pattern area PW.

According to the disclosure, the resin layer RL may be disposed on the pattern area PW. The resin layer RL may be disposed in the recessed area CP and may compensate for a step formed by the recessed area CP. The first adhesive layer AD1 may be disposed on the base substrate VL and the resin layer RL. Since the resin layer RL is disposed in the recessed area CP, the protective layer PF disposed on the first adhesive layer AD1 may remain flat.

In an embodiment, the start point of the recessed area CP defined on the pattern area PW may overlap the first non-folding area NFA1 and/or the second non-folding area NFA2. In this case, the pattern area PW may overlap the first non-folding area NFA1 and/or the second non-folding area NFA2.

Since the resin layer RL in an embodiment is disposed on the pattern area PW, a portion of the resin layer RL may overlap the first non-folding area NFA1 and/or the second non-folding area NFA2, and the disclosure is not limited to a particular embodiment.

Since the window WL includes the pattern area PW overlapping the folding area FA and having a variable thickness according to the disclosure, the base substrate VL may be prevented from being cracked in a folding operation of the electronic device ED. Accordingly, the electronic device ED with improved folding characteristics may be provided.

Since the window WL of the disclosure includes the resin layer RL in the folding area FA, the sensing sensitivity of sensing patterns overlapping the folding area FA among sensing patterns included in the input sensing layer ISP may be deteriorated when compared to the sensing sensitivity of sensing patterns overlapping the first and second non-folding areas NFA1 and NFA2. Therefore, a method for improving the sensitivity of the sensing patterns overlapping the folding area FA among the sensing patterns included in the input sensing layer ISP is desired.

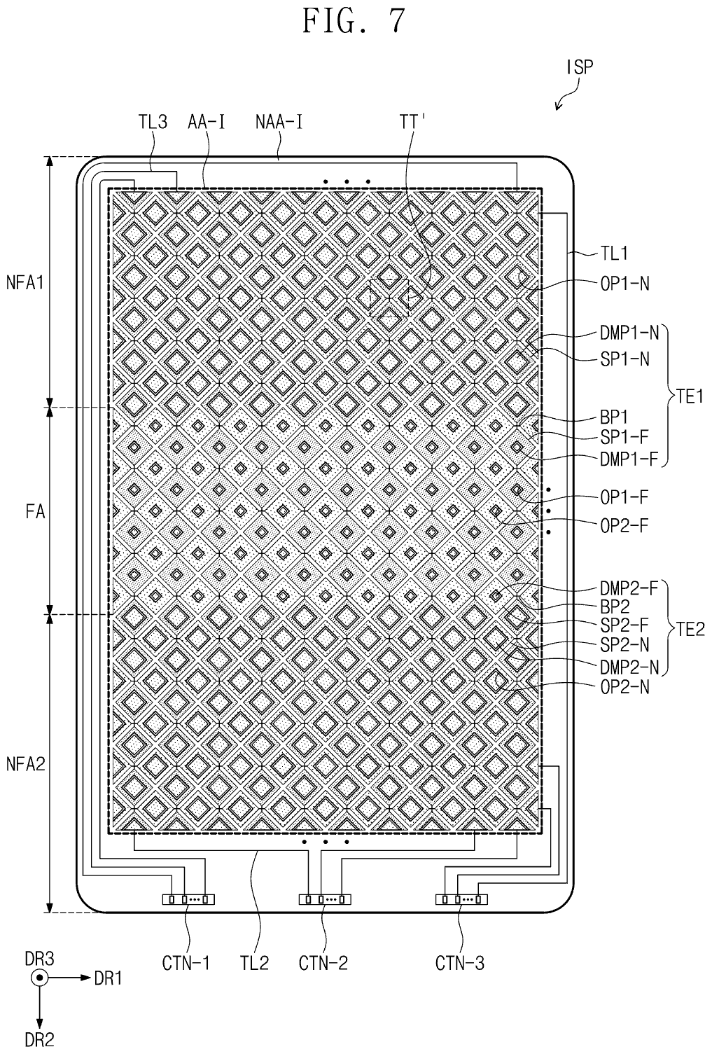

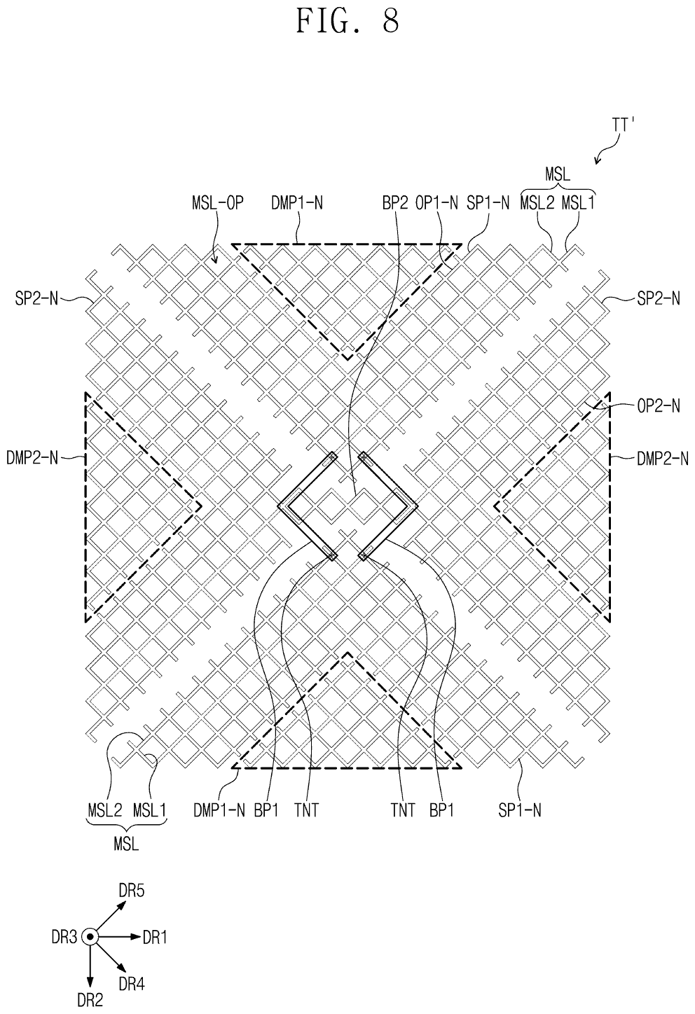

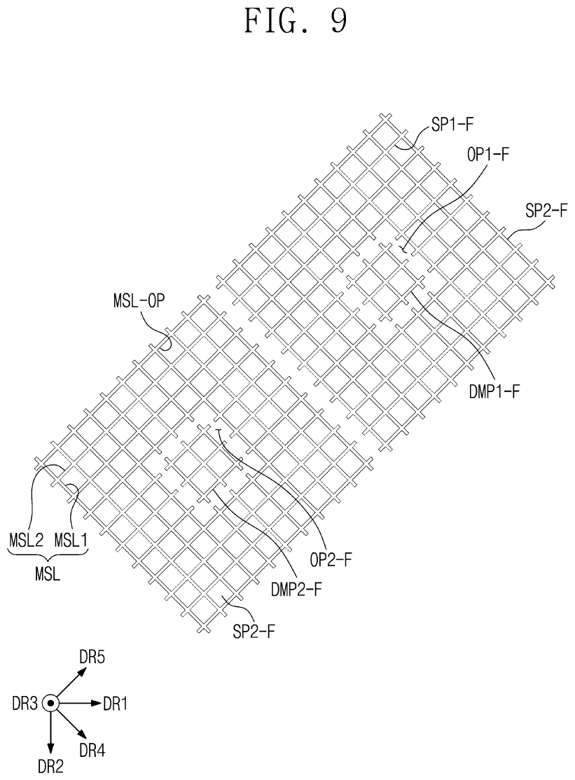

FIG. 7 is a plan view of an embodiment of the input sensing layer according to the disclosure. FIG. 8 is an enlarged plan view illustrating area TT′ of FIG. 6. FIG. 9 is a plan view of an embodiment of sensing patterns according to the disclosure.

Referring to FIG. 7, in this embodiment, the input sensing layer ISP may include a plurality of sensing electrodes TE1 and TE2 and a plurality of sensing lines TL1, TL2, and TL3. In FIG. 7, for convenience of description, a folding area FA of the input sensing layer ISP is illustrated to be larger than the folding area FA in FIG. 5A.

The input sensing layer ISP of the disclosure may sense an external input in a mutual capacitance type. The input sensing layer ISP may increase a change in capacitance between the sensing electrodes TE1 and TE2 when sensing the external input in the mutual capacitance type.

The input sensing layer ISP may be divided into an active area AA-I and a peripheral area NAA-I next (adjacent) to the active area AA-I. The active area AA-I of the input sensing layer ISP may correspond to the display area DA of the display panel DP (refer to FIG. 5A), and the peripheral area NAA-I of the input sensing layer ISP may correspond to the non-display area NDA of the display panel DP. The input sensing layer ISP may include the plurality of sensing electrodes TE1 and TE2. The sensing electrodes TE1 and TE2 may include the first sensing electrodes TE1 and the second sensing electrodes TE2.

The first sensing electrodes TE1 may extend in the second direction DR2 and may be arranged in the first direction DR1. Each of the first sensing electrodes TE1 may include first normal patterns SP1-N, first folding patterns SP1-F, first normal dummy patterns DMP1-N, first folding dummy patterns DMP1-F, and first conductive patterns BP1.

The first normal patterns SP1-N and the first normal dummy patterns DMP1-N may be disposed in the first and second non-folding areas NFA1 and NFA2, and the first folding patterns SP1-F and the first folding dummy patterns DMP1-F may be disposed in the folding area FA. The first conductive patterns BP1 may connect the first normal patterns SP1-N disposed next (adjacent) to each other in the second direction DR2, may connect the first normal pattern SP1-N and the first folding pattern SP1-F disposed next (adjacent) to each other in the second direction DR2, and may connect the first folding patterns SP1-F disposed next (adjacent) to each other in the second direction DR2.

In the embodiment, a first normal opening OP1-N may be defined in each of the first normal patterns SP1-N. One first normal dummy pattern DMP1-N may be disposed in one first normal opening OP1-N. The first normal pattern SP1-N and the first normal dummy pattern DMP1-N disposed in the first normal pattern SP1-N may be insulated from each other. Accordingly, the first normal dummy pattern DMP1-N may be in a floated state.

A first folding opening OP1-F may be defined in each of the first folding patterns SP1-F. One first folding dummy pattern DMP1-F may be disposed in one first folding opening OP1-F. The first folding pattern SP1-F and the first folding dummy pattern DMP1-F disposed in the first folding pattern SP1-F may be insulated from each other. Accordingly, the first folding dummy pattern DMP1-F may be in a floated state.

The second sensing electrodes TE2 may extend in the first direction DR1 and may be arranged in the second direction DR2. Each of the second sensing electrodes TE2 may include second normal patterns SP2-N, second folding patterns SP2-F, second normal dummy patterns DMP2-N, second folding dummy patterns DMP2-F, and second conductive patterns BP2.

The second normal patterns SP2-N and the second normal dummy patterns DMP2-N may be disposed in the first and second non-folding areas NFA1 and NFA2, and the second folding patterns SP2-F and the second folding dummy patterns DMP2-F may be disposed in the folding area FA. The second conductive patterns BP2 may connect the second normal patterns SP2-N disposed next (adjacent) to each other in the first direction DR1, may connect the second normal pattern SP2-N and the second folding pattern SP2-F disposed next (adjacent) to each other in the first direction DR1, and may connect the second folding patterns SP2-F disposed next (adjacent) to each other in the first direction DR1. In this embodiment, the second conductive patterns BP2 may be disposed in the same layer as the second normal patterns SP2-N and the second folding patterns SP2-F and may have a one-body shape with the second normal patterns SP2-N and the second folding patterns SP2-F.

In the embodiment, a second normal opening OP2-N may be defined in each of the second normal patterns SP2-N. One second normal dummy pattern DMP2-N may be disposed in one second normal opening OP2-N. The second normal pattern SP2-N and the second normal dummy pattern DMP2-N disposed in the second normal pattern SP2-N may be insulated from each other. Accordingly, the second normal dummy pattern DMP2-N may be in a floated state.

A second folding opening OP2-F may be defined in each of the second folding patterns SP2-F. One second folding dummy pattern DMP2-F may be disposed in one second folding opening OP2-F. The second folding pattern SP2-F and the second folding dummy pattern DMP2-F disposed in the second folding pattern SP2-F may be insulated from each other. Accordingly, the second folding dummy pattern DMP2-F may be in a floated state.

Although it has been described that the above-described dummy patterns DMP1-N, DMP1-F, DMP2-N, and DMP2-F are floated from the neighboring (adjacent) patterns, the disclosure is not limited thereto, and the dummy patterns DMP1-N, DMP1-F, DMP2-N, and DMP2-F may be connected to each other by a separate sensing line and may receive a bias voltage such as a power supply voltage.

The sensing lines TL1, TL2, and TL3 may include the first sensing lines TL1, the second sensing lines TL2, and the third sensing lines TL3.

The input sensing layer ISP according to the disclosure may define the plurality of upper contact holes CTN-1, CTN-2, and CTN-3 defined in the peripheral area NAA-I. The upper contact holes CTN-1, CTN-2, and CTN-3 may be defined through the first sensing insulation layer IL1 and the second sensing insulation layer IL2. The upper contact holes CTN-1, CTN-2, and CTN-3 may overlap the corresponding lower contact holes CTN1, CTN2, and CTN3 described with reference to FIG. 5A.

First ends of the first sensing lines TL1 may be connected to the second sensing electrodes TE2, and second ends of the first sensing lines TL1 may extend to the third upper contact holes CTN-3. The second ends of the first sensing lines TL1 may be connected to the pads PD (refer to FIG. 5A) through the third lower contact holes CTN3 (refer to FIG. 5A) and the third upper contact holes CTN-3 overlapping each other.

First ends of the second sensing lines TL2 may be connected to first ends of the first sensing electrodes TE1, and second ends of the second sensing lines TL2 may extend to the second upper contact holes CTN-2. The second ends of the second sensing lines TL2 may be connected to the pads PD (refer to FIG. 5A) through the second lower contact holes CTN2 (refer to FIG. 5A) and the second upper contact holes CTN-2 overlapping each other.

First ends of the third sensing lines TL3 may be connected to second ends of the first sensing electrodes TE1, and second ends of the third sensing lines TL3 may extend to the first upper contact holes CTN-1. The second ends of the third sensing lines TL3 may be connected to the pads PD (refer to FIG. 5A) through the first lower contact holes CTN1 (refer to FIG. 5A) and the first upper contact holes CTN-1 overlapping each other.

The first sensing electrodes TE1 in an embodiment of the disclosure may be connected to the second sensing lines TL2 and the third sensing lines TL3. Accordingly, the sensitivity depending on areas may be uniformly maintained for the first sensing electrodes TE1 having a greater length than that of the second sensing electrodes TE2.

The sensing lines TL1, TL2, and TL3 may be connected with the pads PD and may be connected with pads of a flexible circuit board. Accordingly, the sensing electrodes TE1 and TE2 may be electrically connected with the flexible circuit board and the main circuit board connected to the bending area BA (refer to FIG. 5A) of the display panel DP (refer to FIG. 5A).

Referring to FIGS. 8 and 9, the second conductive pattern layer CL2 described with reference to FIG. 5B may be implemented with a mesh structure MSL. The mesh structure MSL may include first mesh lines MSL1 extending in a fourth direction DR4 and second mesh lines MSL2 extending in a fifth direction DR5. The first mesh lines MSL1 and the second mesh lines MSL2 may be connected to define mesh openings MSL-OP. Each of the mesh openings MSL-OP may correspond to the opening IS-OP described with reference to FIG. 5B. The first mesh lines MSL1 and the second mesh lines MSL2 may overlap the pixel defining layer PDL (refer to FIG. 5B).

In the embodiment, the first normal patterns SP1-N, the first folding patterns SP1-F, the first normal dummy patterns DMP1-N, the first folding dummy patterns DMP1-F, the second normal patterns SP2-N, the second folding patterns SP2-F, the second normal dummy patterns DMP2-N, the second folding dummy patterns DMP2-F, and the second conductive patterns BP2 may be included in the second conductive pattern layer CL2 described with reference to FIG. 5B. The first conductive patterns BP1 may be included in the first conductive pattern layer CL1 described with reference to FIG. 5B.

As illustrated in FIG. 8, the first normal patterns SP1-N may be arranged in the second direction DR1. The first normal patterns SP1-N next (adjacent) to each other in the second direction DR2 may be connected through the first conductive patterns BP1.

The first normal patterns SP1-N may be connected with a corresponding first conductive pattern BP1 through sensing contact holes TNT defined in the second sensing insulation layer IL2 (refer to FIG. 5B). Accordingly, even though the first normal patterns SP1-N are disposed in the same layer as the second normal patterns SP2-N and the second normal dummy patterns DMP2-N, the first normal patterns SP1-N may be insulated from the second normal patterns SP2-N and the second normal dummy patterns DMP2-N through the first conductive pattern BP1 disposed on the first sensing insulation layer IL1. Thus, the first conductive pattern BP1 and the second conductive pattern BP2 disposed in different layers may overlap each other when viewed from above the plane.

The first normal dummy patterns DMP1-N may be disposed in the first normal openings OP1-N defined in the first normal patterns SP1-N, and the second normal dummy patterns DMP2-N may be disposed in the second normal openings OP2-N defined in the second normal patterns SP2-N.

In the embodiment, likewise to the first normal patterns SP1-N and the second normal patterns SP2-N, the first normal dummy patterns DMP1-N and the second normal dummy patterns DMP2-N may be implemented with the mesh structure MSL. Accordingly, even though the first normal dummy patterns DMP1-N and the second normal dummy patterns DMP2-N are disposed in the first normal patterns SP1-N and the second normal patterns SP2-N, the shapes of the patterns may be prevented from being visible from the outside.

In FIG. 9, one first folding pattern SP1-F and one second folding pattern SP2-F are illustrated as an example. One first folding opening OP1-F may be defined in the first folding pattern SP1-F, and one second folding opening OP2-F may be defined in the second folding pattern SP2-F. One first folding dummy pattern DMP1-F may be disposed in the one first folding opening OP1-F, and one second folding dummy pattern DMP2-F may be disposed in the one second folding opening OP2-F. In an embodiment, the first folding dummy pattern DMP1-F and the second folding dummy pattern DMP2-F may have the same shape and area.

Referring back to FIG. 7, the normal dummy patterns DMP1-N and DMP2-N may have the same area as each other, and the folding dummy patterns DMP1-F and DMP2-F may have the same area as each other. Correspondingly, the normal openings OP1-N and OP2-N may have the same area as each other, and the folding openings OP1-F and OP2-F may have the same area as each other. In addition, the areas of the normal dummy patterns DMP1-N and DMP2-N may be greater than the areas of the folding dummy patterns DMP1-F and DMP2-F. Correspondingly, the areas of the normal openings OP1-N and OP2-N may be greater than the areas of the folding openings OP1-F and OP2-F.

Since the normal dummy patterns DMP1-N and DMP2-N larger than the folding dummy patterns DMP1-F and DMP2-F are disposed in the normal patterns SP1-N and SP2-N, the areas of the normal openings OP1-N and OP2-N corresponding to the normal dummy patterns DMP1-N and DMP2-N may be greater than the areas of the folding openings OP1-F and OP2-F. Accordingly, the sensing sensitivity of the folding patterns SP1-F and SP2-F disposed in the folding area FA may be relatively improved when compared to the sensing sensitivity of the normal patterns SP1-N and SP2-N disposed in the non-folding areas NFA1 and NFA2.

The areas of the normal patterns SP1-N and SP2-N including the openings may be equal to the areas of the folding patterns SP1-F and SP2-F including the openings.

In the embodiment, each of the normal dummy patterns DMP1-N and DMP2-N, the folding dummy patterns DMP1-F and DMP2-F, the normal openings OP1-N and OP2-N, and the folding openings OP1-F and OP2-F may have a rhombic shape.

According to the disclosure, when the resin layer RL (refer to FIG. 6) is disposed in the folding area FA in the foldable electronic device ED (refer to FIG. 3), the reduced sensing sensitivity in the folding area FA may be compensated for by controlling the areas of the dummy patterns. Accordingly, the electronic device ED including the input sensing layer ISP having constant sensing sensitivity in the entirety of the area may be provided.

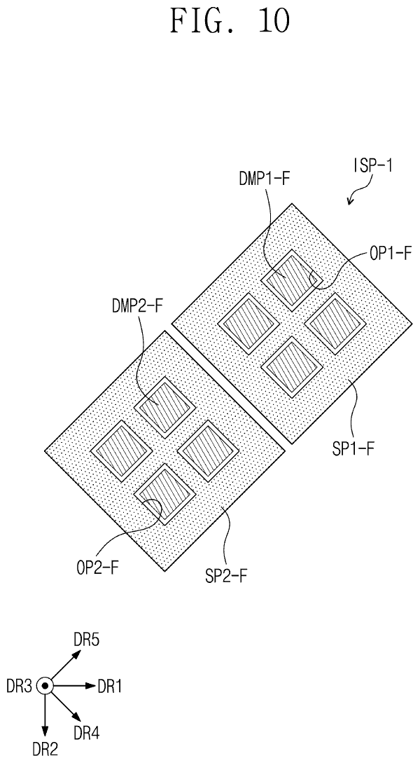

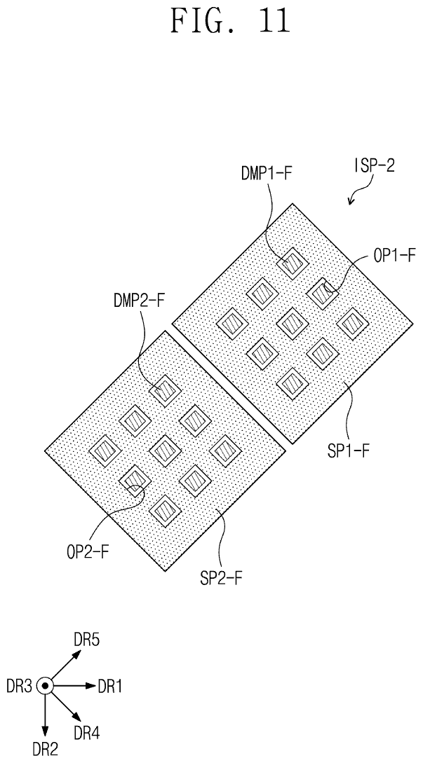

FIG. 10 is a plan view of an embodiment of sensing patterns according to the disclosure. FIG. 11 is a plan view of sensing patterns according to the disclosure. Components identical/similar to the components described with reference to FIGS. 5A to 9 will be assigned with identical/similar reference numerals, and repetitive descriptions will be omitted. In FIGS. 10 and 11, one first folding pattern SP1-F and one second folding pattern SP2-F described with reference to FIG. 7 are illustrated. In addition, the shape of the mesh structure MSL described with reference to FIG. 9 is omitted.

Referring to FIG. 10, an input sensing layer ISP-1 in an embodiment may include the first folding pattern SP1-F and the second folding pattern SP2-F disposed in the folding area FA (refer to FIG. 7). In this embodiment, n times n (n×n) first folding openings OP1-F (n being a natural number greater than 0) may be defined in the first folding pattern SP1-F, and n×n second folding openings OP2-F (n being a natural number greater than 0) may be defined in the second folding pattern SP2-F. In this embodiment, n may be equal to 2.

First folding dummy patterns DMP1-F disposed in four first folding openings OP1-F, respectively, may be included in the one first folding pattern SP1-F. In this embodiment, each of the first folding openings OP1-F and the first folding dummy patterns DMP1-F may have a rhombic shape.

Two first folding dummy patterns DMP1-F may be arranged in the second direction DR2, and the remaining two first folding dummy patterns DMP1-F may be arranged in the first direction DR1. The first folding dummy patterns DMP1-F arranged in the second direction DR2 and the first folding dummy patterns DMP1-F arranged in the first direction DR1 may be spaced apart from each other in the fourth direction DR4 and the fifth direction DR5.

Second folding dummy patterns DMP2-F disposed in four second folding openings OP2-F, respectively, may be included in the one second folding pattern SP2-F. In this embodiment, each of the second folding openings OP2-F and the second folding dummy patterns DMP2-F may have a rhombic shape.

Two second folding dummy patterns DMP2-F may be arranged in the second direction DR2, and the remaining two second folding dummy patterns DMP2-F may be arranged in the first direction DR1. The second folding dummy patterns DMP2-F arranged in the second direction DR2 and the second folding dummy patterns DMP2-F arranged in the first direction DR1 may be spaced apart from each other in the fourth direction DR4 and the fifth direction DR5.

The arrangements and numbers of normal dummy patterns and normal openings defined in the normal patterns SP1-N and SP2-N described with reference to FIG. 7 may be the same as the arrangements and numbers of folding dummy patterns DMP1-F and DMP2-F and folding openings OP1-F and OP2-F included in the first folding pattern SP1-F and the second folding pattern SP2-F.

Referring to FIG. 11, an input sensing layer ISP-2 in an embodiment may include the first folding pattern SP-F and the second folding pattern SP2-F disposed in the folding area FA (refer to FIG. 7). In this embodiment, n×n first folding openings OP1-F (n being a natural number greater than 0) may be defined in the first folding pattern SP1-F, and n×n second folding openings OP2-F (n being a natural number greater than 0) may be defined in the second folding pattern SP2-F. In this embodiment, n may be equal to 3.

First folding dummy patterns DMP1-F disposed in nine first folding openings OP1-F, respectively, may be included in the one first folding pattern SP1-F. In this embodiment, each of the first folding openings OP1-F and the first folding dummy patterns DMP1-F may have a rhombic shape.

Each of three first dummy groups may include three first folding dummy patterns DMP1-F arranged in the fifth direction DR5. The three first dummy groups may be arranged in the fourth direction DR4.

Second folding dummy patterns DMP2-F disposed in nine second folding openings OP2-F, respectively, may be included in the one second folding pattern SP2-F. In this embodiment, each of the second folding openings OP2-F and the second folding dummy patterns DMP2-F may have a rhombic shape.

Each of three second dummy groups may include three second folding dummy patterns DMP2-F arranged in the fifth direction DR5. The three second dummy groups may be arranged in the fourth direction DR4.

The arrangements and numbers of normal dummy patterns and normal openings defined in the normal patterns SP1-N and SP2-N described with reference to FIG. 7 may be the same as the arrangements and numbers of folding dummy patterns DMP1-F and DMP2-F and folding openings OP1-F and OP2-F included in the first folding pattern SP1-F and the second folding pattern SP2-F.

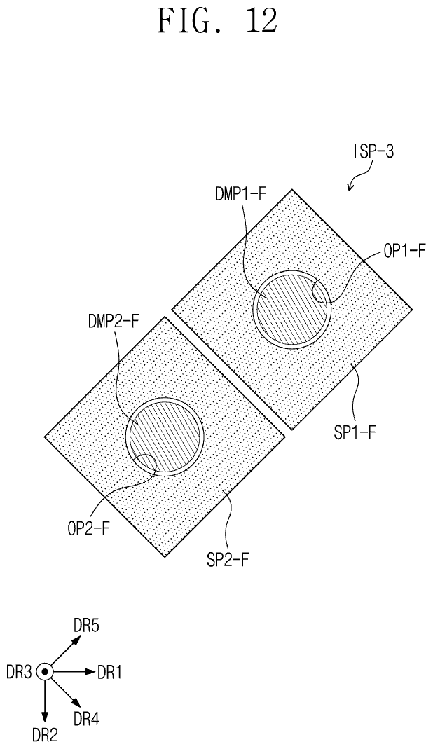

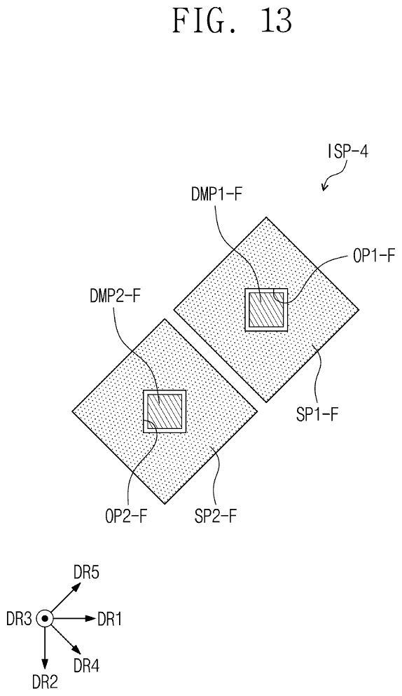

FIG. 12 is a plan view of an embodiment of sensing patterns according to the disclosure. FIG. 13 is a plan view of sensing patterns according to the disclosure. Components identical/similar to the components described with reference to FIGS. 5A to 9 will be assigned with identical/similar reference numerals, and repetitive descriptions will be omitted. In FIGS. 12 and 13, one first folding pattern SP1-F and one second folding pattern SP2-F described with reference to FIG. 7 are illustrated. In addition, the shape of the mesh structure MSL described with reference to FIG. 9 is omitted.

Referring to FIG. 12, an input sensing layer ISP-3 in an embodiment may include the first folding pattern SP-F and the second folding pattern SP2-F disposed in the folding area FA (refer to FIG. 7). In this embodiment, the shape of the first folding pattern SP1-F including the first folding opening OP1-F may be different from the shape of the first folding opening OP1-F and the shape of the first folding dummy pattern DMP1-F. In addition, the shape of the second folding pattern SP2-F including the second folding opening OP2-F may be different from the shape of the second folding opening OP2-F and the shape of the second folding dummy pattern DMP2-F.

In the embodiment, the outer periphery of each of the first folding pattern SP1-F and the second folding pattern SP2-F may have a rhombic shape, and the first folding opening OP1-F, the second folding opening OP2-F, the first folding dummy pattern DMP1-F, and the second folding dummy pattern DMP2-F may have a circular shape.

The normal patterns disposed in the non-folding areas NFA1 and NFA2 (refer to FIG. 7) may have the same shape as that of the first folding pattern SP1-F and the second folding pattern SP2-F. The dummy normal patterns disposed in the non-folding areas NFA1 and NFA2 (refer to FIG. 7) may have the same shape as that of the first folding dummy pattern DMP1-F and the second folding dummy pattern DMP2-F. The normal openings may have the same shape as that of the first folding opening OP1-F and the second folding opening OP2-F.

Referring to FIG. 13, an input sensing layer ISP-4 in an embodiment may include the first folding pattern SP1-F and the second folding pattern SP2-F disposed in the folding area FA (refer to FIG. 7). In this embodiment, the shape of the first folding pattern SP1-F including the first folding opening OP1-F may be different from the shape of the first folding opening OP1-F and the shape of the first folding dummy pattern DMP1-F. In addition, the shape of the second folding pattern SP2-F including the second folding opening OP2-F may be different from the shape of the second folding opening OP2-F and the shape of the second folding dummy pattern DMP2-F.

In the embodiment, the outer periphery of each of the first folding pattern SP1-F and the second folding pattern SP2-F may have a rhombic shape, and the first folding opening OP1-F, the second folding opening OP2-F, the first folding dummy pattern DMP1-F, and the second folding dummy pattern DMP2-F may have a square shape. However, without being limited thereto, the first folding opening OP1-F, the second folding opening OP2-F, the first folding dummy pattern DMP1-F, and the second folding dummy pattern DMP2-F may have a quadrangular shape, e.g., rectangular shape or a polygonal shape.

The normal patterns disposed in the non-folding areas NFA1 and NFA2 (refer to FIG. 7) may have the same shape as that of the first folding pattern SP1-F and the second folding pattern SP2-F. The dummy normal patterns disposed in the non-folding areas NFA1 and NFA2 (refer to FIG. 7) may have the same shape as that of the first folding dummy pattern DMP1-F and the second folding dummy pattern DMP2-F. The normal openings may have the same shape as that of the first folding opening OP1-F and the second folding opening OP2-F.

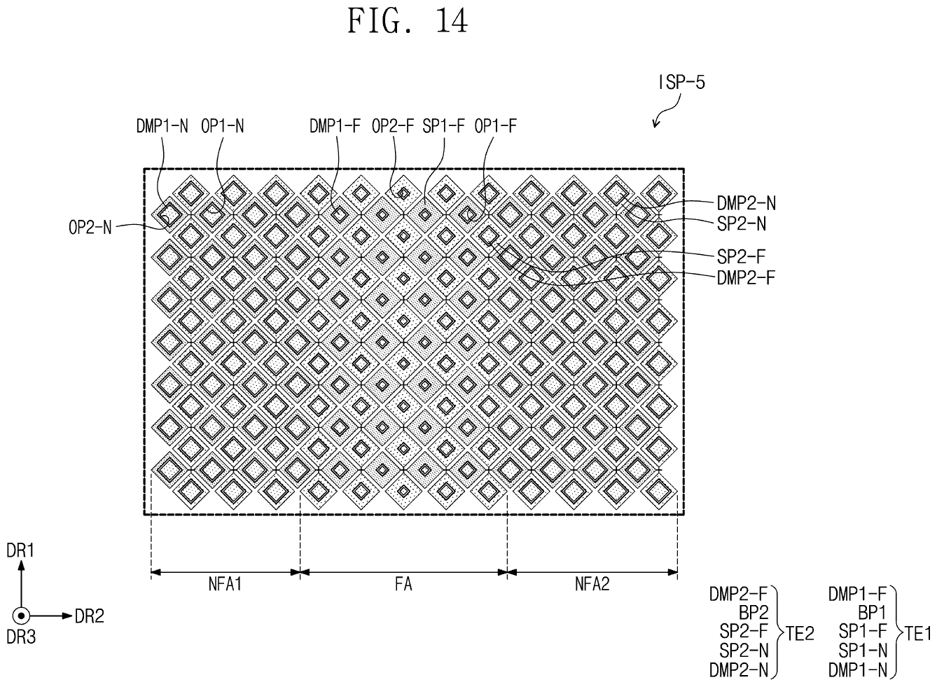

FIG. 14 is a plan view of an embodiment of an input sensing layer according to the disclosure. Components identical/similar to the components described with reference to FIGS. 5A to 9 will be assigned with identical/similar reference numerals, and repetitive descriptions will be omitted. Among the components of the input sensing layer ISP described with reference to FIG. 7, only some of the patterns disposed in the active area AA are illustrated in FIG. 14.

Referring to FIG. 14, the input sensing layer ISP-5 may include sensing electrodes TE1 and TE2. The sensing electrodes TE1 and TE2 may include the first sensing electrodes TE1 and the second sensing electrodes TE2.

The first sensing electrodes TE1 may extend in the second direction DR2 and may be arranged in the first direction DR1. Each of the first sensing electrodes TE1 may include first normal patterns SP1-N, first folding patterns SP1-F, first normal dummy patterns DMP1-N, first folding dummy patterns DMP1-F, and first conductive patterns BP1.

The first normal patterns SP1-N and the first normal dummy patterns DMP1-N may be disposed in the first and second non-folding areas NFA1 and NFA2, and the first folding patterns SP1-F and the first folding dummy patterns DMP1-F may be disposed in the folding area FA. The first conductive patterns BP1 may connect the first normal patterns SP1-N disposed next (adjacent) to each other in the second direction DR2, may connect the first normal pattern SP1-N and the first folding pattern SP1-F disposed next (adjacent) to each other in the second direction DR2, and may connect the first folding patterns SP1-F disposed next (adjacent) to each other in the second direction DR2.

In the embodiment, a first normal opening OP1-N may be defined in each of the first normal patterns SP1-N. One first normal dummy pattern DMP1-N may be disposed in one first normal opening OP1-N. The first normal pattern SP1-N and the first normal dummy pattern DMP1-N disposed in the first normal pattern SP1-N may be insulated from each other. Accordingly, the first normal dummy pattern DMP1-N may be in a floated state.

A first folding opening OP1-F may be defined in each of the first folding patterns SP1-F. One first folding dummy pattern DMP1-F may be disposed in one first folding opening OP1-F. The first folding pattern SP1-F and the first folding dummy pattern DMP1-F disposed in the first folding pattern SP1-F may be insulated from each other. Accordingly, the first folding dummy pattern DMP1-F may be in a floated state.

The second sensing electrodes TE2 may extend in the first direction DR1 and may be arranged in the second direction DR2. Each of the second sensing electrodes TE2 may include second normal patterns SP2-N, second folding patterns SP2-F, second normal dummy patterns DMP2-N, second folding dummy patterns DMP2-F, and second conductive patterns BP2.

The second normal patterns SP2-N and the second normal dummy patterns DMP2-N may be disposed in the first and second non-folding areas NFA1 and NFA2, and the second folding patterns SP2-F and the second folding dummy patterns DMP2-F may be disposed in the folding area FA. The second conductive patterns BP2 may connect the second normal patterns SP2-N disposed next (adjacent) to each other in the second direction DR2, may connect the second normal pattern SP2-N and the second folding pattern SP2-F disposed next (adjacent) to each other in the second direction DR2, and may connect the second folding patterns SP2-F disposed next (adjacent) to each other in the second direction DR2. In this embodiment, the second conductive patterns BP2 may be disposed in the same layer as the second normal patterns SP2-N and the second folding patterns SP2-F and may have a one-body shape with the second normal patterns SP2-N and the second folding patterns SP2-F.

In the embodiment, a second normal opening OP2-N may be defined in each of the second normal patterns SP2-N. One second normal dummy pattern DMP2-N may be disposed in one second normal opening OP2-N. The second normal pattern SP2-N and the second normal dummy pattern DMP2-N disposed in the second normal pattern SP2-N may be insulated from each other. Accordingly, the second normal dummy pattern DMP2-N may be in a floated state.

A second folding opening OP2-F may be defined in each of the second folding patterns SP2-F. One second folding dummy pattern DMP2-F may be disposed in one second folding opening OP2-F. The second folding pattern SP2-F and the second folding dummy pattern DMP2-F disposed in the second folding pattern SP2-F may be insulated from each other. Accordingly, the second folding dummy pattern DMP2-F may be in a floated state.

In the embodiment, the shapes of the folding dummy patterns DMP1-F and DMP2-F disposed in the folding area FA may be varied. As illustrated in FIG. 6, the resin layer RL may have the smallest thickness at the boundaries between the folding area FA and the non-folding areas NFA1 and NFA2 and may have the greatest thickness at the center of the folding area FA.

Accordingly, the sensing sensitivity at the center of the folding area FA may be reduced when compared to the sensing sensitivity at the boundaries.

In the embodiment, the areas of the folding dummy patterns DMP1-F and DMP2-F may be decreased toward the center of the folding area FA from the boundaries. In addition, the areas of the folding openings OP1-F and OP2-F may be decreased toward the center of the folding area FA from the boundaries.

As the areas of the folding dummy patterns DMP1-F and DMP2-F are decreased, the areas of the folding patterns SP1-F and SP2-F may be increased, and thus the sensing sensitivity at the center of the folding area FA may be prevented from being reduced.

According to the disclosure, the reduced sensing sensitivity in the folding area in the foldable electronic device may be compensated for by controlling the areas of the dummy patterns. Accordingly, the electronic device including the input sensing layer having constant sensing sensitivity in the entirety of the area may be provided.

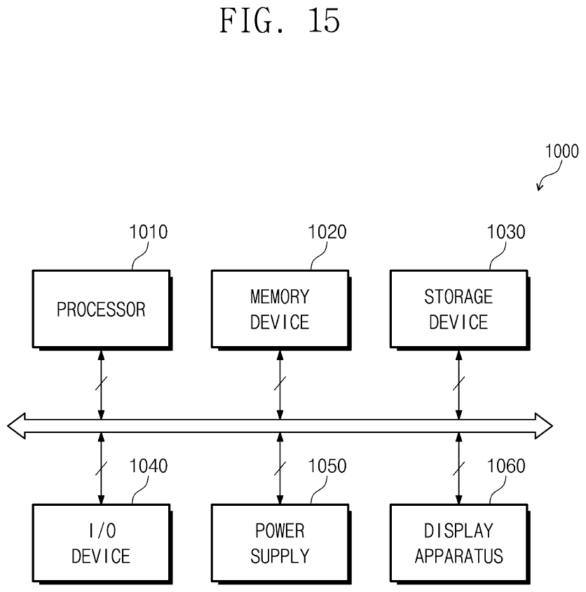

FIG. 15 is a block diagram illustrating an electronic device according to an embodiment.

Referring to FIG. 15, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device ED of FIG. 1. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

In an embodiment the electronic device may be implemented as a smartphone. However the embodiments of the present disclosure may be exemplary and may not be limited to this. For example, the electronic device 1000 may be implemented as a mobile phone, a video phone, a smart pad, a smart watch, a television, a tablet PC, a vehicle display, a computer monitor, a notebook computer, a head-mounted display device, etc. In addition, the electronic device 1000 may be a television, a monitor, a notebook computer, or a tablet. In addition, the electronic device 1000, may be a car.

While the disclosure has been described with reference to embodiments thereof, it will be apparent to those of ordinary skill in the art that various changes and modifications may be made thereto without departing from the spirit and scope of the disclosure as set forth in the following claims.

What is claimed is:

1. An electronic device comprising:
a display panel including a folding area folded about a folding axis extending in a first direction and non-folding areas spaced apart from each other in a second direction crossing the first direction with the folding area therebetween;
an input sensing layer disposed on the display panel, the input sensing layer including:
normal patterns overlapping the non-folding areas, the normal patterns including normal openings defined therein, respectively;
folding patterns overlapping the folding area, the folding patterns including folding openings defined therein, respectively;
normal dummy patterns disposed in the normal openings; and
folding dummy patterns disposed in the folding openings, the folding dummy patterns having a smaller area than an area of the normal dummy patterns; and
a window disposed on the input sensing layer.

2. The electronic device of claim 1, wherein the window includes:
a base substrate including a pattern area overlapping the folding area and recessed in a direction toward the display panel and flat areas overlapping the non-folding areas;
a resin layer disposed on the pattern area;
a protective layer disposed over the base substrate; and
a window adhesive layer disposed between the base substrate and the protective layer.

3. The electronic device of claim 2, wherein the pattern area has a decreasing thickness toward the center of the folding area from boundaries between the folding area and the non-folding areas.

4. The electronic device of claim 3, wherein the resin layer has a shape corresponding to a recessed area of the pattern area.

5. The electronic device of claim 3, wherein areas of the folding dummy patterns are decreased toward the center of the folding area from the boundaries between the folding area and the non-folding areas.

6. The electronic device of claim 1, wherein the folding dummy patterns have a same area as each other, and
wherein the normal dummy patterns have a same area as each other.

7. The electronic device of claim 1, wherein each of the normal openings, the folding openings, the normal dummy patterns, and the folding dummy patterns has a rhombic shape.

8. The electronic device of claim 7, wherein a number of folding openings defined in one folding pattern and a number of folding dummy patterns disposed in the one folding pattern are n times n (n being a natural number greater than 0).

9. The electronic device of claim 8, wherein a number of normal openings defined in one normal pattern is equal to a number of folding openings defined in one folding pattern, and
wherein a number of normal dummy patterns disposed in the one normal pattern is equal to as a number of folding dummy patterns disposed in the one folding pattern.

10. The electronic device of claim 1, wherein the input sensing layer includes:
a first sensing insulation layer disposed on the display panel;
a first conductive pattern layer disposed on the first sensing insulation layer, the first conductive pattern layer including some of the normal patterns and some of the folding patterns;
a second sensing insulation layer disposed on the first sensing insulation layer and configured to cover the first conductive pattern layer;
a second conductive pattern layer disposed on the second sensing insulation layer, the second conductive pattern layer including remaining normal patterns, remaining folding patterns, the normal dummy patterns, and the folding dummy patterns; and
a third sensing insulation layer disposed on the second sensing insulation layer and configured to cover the second conductive pattern layer.

11. The electronic device of claim 10, wherein the normal patterns, the folding patterns, the normal dummy patterns, and the folding dummy patterns included in the second conductive layer are implemented with mesh lines configured to extend in inclined directions crossing the first direction and the second direction, and
wherein the mesh lines define mesh openings.

12. The electronic device of claim 11, wherein the display panel includes:
a base layer;
a circuit element layer including transistors and insulating layers disposed on the base layer;
a display element layer including light emitting elements, each of which includes a first electrode, a second electrode, and an emissive layer connected with the transistors, and a pixel defining layer having light emitting openings defined therein to expose the first electrodes; and
an encapsulation layer disposed on the display element layer, the encapsulation layer including inorganic layers and an organic layer disposed between the inorganic layers.

13. The electronic device of claim 12, wherein the mesh lines are disposed on the pixel defining layer, and the mesh openings overlap the light emitting openings.

14. The electronic device of claim 12, wherein the first sensing insulation layer is directly disposed on the encapsulation layer.

15. The electronic device of claim 1, wherein each of the normal openings, the folding openings, the normal dummy patterns, and the folding dummy patterns has a circular shape or a quadrangular shape.

16. The electronic device of claim 1, wherein outer peripheries of the normal patterns have a same shape as a shape of outer peripheries of the folding patterns.

17. The electronic device of claim 1, wherein the folding axis is defined above an upper surface of the window, and
wherein in a first mode, the electronic device is folded in an in-folding manner so that portions of the upper surface of the window overlapping the non-folding areas face each other, and in a second mode, the electronic device is unfolded.

18. The electronic device of claim 1, wherein the folding axis is defined below a rear surface of the display panel, and
wherein in a first mode, the electronic device is folded in an out-folding manner so that portions of the rear surface of the display panel overlapping the non-folding areas face each other, and in a second mode, the electronic device is unfolded.

19. The electronic device of claim 1, further comprising:
a support plate disposed under the display panel, the support plate having holes defined therein to overlap the folding area.

20. The electronic device of claim 1, wherein the display panel includes a first area overlapping the non-folding areas and the folding area, a second area spaced apart from the first area in the second direction, and a bending area disposed between the first area and the second area, and
wherein the bending area is bent about a bending axis extending in the first direction.
